(19) United States
(12) Patent Application Publication
(10) Pub. No.: US 2014/0054680 A1
(43) Pub. Date: Feb. 27, 2014

(54) METHOD OF FORMING GROUP III NITRIDE SEMICONDUCTOR, METHOD OF FABRICATING SEMICONDUCTOR DEVICE, GROUP III NITRIDE SEMICONDUCTOR DEVICE, METHOD OF PERFORMING THERMAL TREATMENT

(71) Applicant: SUMITOMO ELECTRIC INDUSTRIES, LTD., Osaka (JP)

(72) Inventors: Shin HASHIMOTO, Itami-shi (JP); Takao NAKAMURA, Itami-shi (JP); Hiroshi AMANO, Nagoya-city (JP)

(73) Assignee: SUMITOMO ELECTRIC INDUSTRIES, LTD., Osaka (JP)

(21) Appl. No.: 13/972,263

(22) Filed: Aug. 21, 2013

Related U.S. Application Data
(60) Provisional application No. 61/694,512, filed on Aug. 29, 2012.

(30) Foreign Application Priority Data
Aug. 22, 2012 (JP) 2012-183350

(51) Int. Cl. H01L 21/324; H01L 29/78; H01L 29/20; H01L 29/872; H01L 29/66; H01L 21/66

(52) U.S. Cl. CPC H01L 21/3242; H01L 21/3245; H01L 29/66143; H01L 29/66666; H01L 22/20; H01L 29/2003; H01L 29/872; H01L 29/7827
USPC 257/329; 438/796; 438/508; 438/572; 438/285; 438/5; 257/615; 257/472

(57) ABSTRACT

A method of forming a group III nitride semiconductor comprises: preparing a group III nitride semiconductor which contains a p-type dopant or an n-type dopant; and performing a treatment of the group III nitride semiconductor by using a reducing gas and a nitrogen source gas to form a conductive group III nitride semiconductor. The treatment includes performing a first treatment of the group III nitride semiconductor by using a first treatment gas including the reducing gas and the nitrogen source gas, which are supplied to a treatment apparatus at a first flow rate and a second flow rate, respectively, and after the first treatment is performed, performing a second treatment of the group III nitride semiconductor by using a second treatment gas including the reducing gas and the nitrogen source gas, which are supplied to the treatment apparatus at a third flow rate and a fourth flow rate, respectively.

### CROSS REFERENCE TO RELATED APPLICATIONS

This application is related to and claims priority under 35 U.S.C. 119 to U.S. a provisional patent application No. 61/694,512, filed Aug. 29, 2012, entitled “METHOD OF FORMING GROUP III NITRIDE SEMICONDUCTOR, METHOD OF FABRICATING SEMICONDUCTOR DEVICE, GROUP III NITRIDE SEMICONDUCTOR DEVICE, METHOD OF PERFORMING THERMAL TREATMENT,” and a Japanese patent application No. 2012-183350, filed Aug. 22, 2012, entitled “METHOD OF FORMING GROUP III NITRIDE SEMICONDUCTOR, METHOD OF FABRICATING SEMICONDUCTOR DEVICE, GROUP III NITRIDE SEMICONDUCTOR DEVICE, METHOD OF PERFORMING THERMAL TREATMENT,” and incorporated by reference in their entirety.

### BACKGROUND OF THE INVENTION

1. Field of the Invention

The present invention relates to a method of forming a group III nitride semiconductor, a method of fabricating a semiconductor device, a method of performing a thermal treatment of a group III nitride semiconductor, and a group III nitride semiconductor device.

2. Related Background Art

Patent Document 1 discloses a method of forming a p-type gallium nitride based semiconductor region by a method of ion implantation. Non-Patent Document 1 discloses formation of a p-type semiconductor by the ion implantation method. Non-Patent Document 2 discloses a method of forming a p-type semiconductor by a thermal diffusion method.
Patent Document 1: Japanese Patent Application Laid-open No. 2009-170604
Non-Patent Document 1: Journal of Applied Physics, vol. 90 (2001) 3750
Non-Patent Document 2: Proceedings of the 68th JSAP meeting 4p-N-5

### SUMMARY OF THE INVENTION

In Non-Patent Document 1, the p-type semiconductor is formed by the ion implantation method. After undoped GaN on a sapphire substrate is grown, beryllium (Be) and oxygen (O) are co-implanted into the epitaxial film, and annealing is carried out in a nitrogen (N₂) atmosphere in order to recover damage caused by the ion implantation. Thereafter, Hall measurement of the annealed GaN is performed to show that the annealed GaN exhibits p-type conductivity. On the other hand, magnesium (Mg) and oxygen (O) are co-implanted into the epitaxial film, and annealing is carried out in the nitrogen (N₂) atmosphere in order to recover damage caused by the ion implantation. This annealed GaN does not exhibit p-type conductivity at all.

In Non-Patent Document 2, the p-type semiconductor is formed by the thermal diffusion method. After a Mg/Ni/Pt electrode is fabricated by an electron beam evaporation method on undoped GaN formed on a sapphire substrate, a treatment for thermal diffusion of Mg is performed in an ammonia atmosphere. Further, activation annealing of the GaN that has been subjected to the thermal diffusion treatment is performed. An electrode for Hall measurement is fabricated on the annealed GaN. According to the Hall measurement, the sample exhibits the p-type characteristics.

In the disclosure of each of the NON-Patent Documents listed above, limitation is in the method of introducing a dopant, and a co-implantation method in which a desired dopant and an additional dopant different from the desired dopant is required.

An object of the present invention is to provide a method of forming a group III nitride semiconductor capable of providing the group III nitride semiconductor having an excellent conductivity, another object of the present invention is to provide a method of fabricating a semiconductor device capable of providing the group III nitride semiconductor having an excellent conductivity, and still another object of the present invention is to provide a method of performing a thermal treatment of the group III nitride semiconductor capable of providing the group III nitride semiconductor having an excellent conductivity. In addition, yet another object of the present invention is to provide a group III nitride semiconductor device including the group III nitride semiconductor having an excellent conductivity.

One aspect of the present invention relates to a method of performing a thermal treatment of a group III nitride semiconductor. This method includes the steps of (a) preparing an ion-implanted group III nitride semiconductor, and (b) performing the thermal treatment on the ion-implanted group III nitride semiconductor at a temperature in a range of not less than 800 degrees Celsius and not more than 1450 degrees Celsius by using a nitrogen source gas capable of providing a nitrogen source for a constituent element of the ion-implanted group III nitride semiconductor and a reducing gas capable of providing a reducing atmosphere. The thermal treatment includes the step of performing a first treatment in which a flow rate of the reducing gas is more than zero, and the step of performing a second treatment in which a flow rate of the nitrogen source gas is more than zero. The flow rate of the nitrogen source gas in the first treatment is less than the flow rate of the nitrogen source gas in the second treatment. As an example of the condition, the thermal treatment includes the step of performing a first treatment in which the flow rate of the reducing gas is not less than the flow rate of the nitrogen source gas, and the step of performing a second treatment in which the flow rate of the nitrogen source gas is more than the flow rate of the reducing gas.

According to this thermal treatment method, the flow rate of the reducing gas is more than zero in the first treatment, the flow rate of the nitrogen source gas is more than zero in the second treatment, the flow rate of the nitrogen source gas in the first treatment is less than the flow rate of the nitrogen source gas in the second treatment, and the first treatment and the second treatment are performed alternately, and hence rearrangement of atoms and recrystallization are caused.

In the thermal treatment method according to the aspect of the present invention, the first treatment and the second treatment can be performed alternately. In this thermal treatment method, the first treatment and the second treatment are repeatedly performed, and hence both the first treatment and the second treatment can further facilitate the rearrangement of atoms and the recrystallization, resulting in the facilitation of the activation of the dopant.

One aspect of the present invention relates to a method of performing a thermal treatment of a group III nitride semiconductor. This method includes the steps of (a) preparing an ion-implanted group III nitride semiconductor, and (b) performing the thermal treatment on the ion-implanted group III nitride semiconductor at a temperature in a range of not less than 800 degrees Celsius and not more than 1450 degrees Celsius by using a nitrogen source gas serving as a nitrogen source for the group III nitride semiconductor and a reducing gas capable of providing a reducing atmosphere capable of reducing the group III nitride semiconductor. The thermal treatment adjusts a flow rate of the reducing gas and a flow rate of the nitrogen source gas to perform a first treatment in which the ion-implanted group III nitride semiconductor is exposed to the reducing atmosphere, and also perform, after the first treatment, a second treatment in which the thermal treatment of the ion-implanted group III nitride semiconductor is performed while a process gas including the nitrogen source gas is supplied. In addition, the first treatment and the second treatment are preferably repeated.

According to this thermal treatment method, the exposure to the reducing atmosphere can cause migration of atoms in the ion-implanted group III nitride semiconductor. In addition, since the treatment in which the ion-implanted group III nitride semiconductor is exposed to the atmosphere containing the nitrogen source gas after the above migration, the ion-implanted dopant atom is taken into the group III nitride semiconductor by the rearrangement of atoms and the recrystallization. Further, the alternation of the exposure to the reducing atmosphere and the exposure to the atmosphere containing the nitrogen source gas can facilitate the migration and the rearrangement of atoms, and recrystallization, and this further facilitates the activation of the dopant atom.

Another aspect of the present invention relates to a method of performing a thermal treatment of a group III nitride semiconductor. This method includes the steps of (a) preparing a group III nitride semiconductor containing at least one of a p-type dopant and an n-type dopant, and (b) performing a treatment of the group III nitride semiconductor by using a reducing gas and a nitrogen source gas.

The treatment includes the step of performing a first thermal treatment of the group III nitride semiconductor while supplying a first treatment gas including the reducing gas having a first flow rate and the nitrogen source gas having a second flow rate to a treatment apparatus, and the step of supplying a second treatment gas including the reducing gas having a third flow rate and the nitrogen source gas having a fourth flow rate to the treatment apparatus to perform a second thermal treatment of the group III nitride semiconductor after the first thermal treatment is performed. In the first thermal treatment, the reducing gas is supplied at the first flow rate, the nitrogen source gas is supplied at the second flow rate, the first flow rate is more than zero, and the second flow rate is not less than zero. In the second thermal treatment, the reducing gas is supplied at the third flow rate, the nitrogen source gas is supplied at the fourth flow rate, the fourth flow rate is more than zero, and the third flow rate is not less than zero. In addition, the second flow rate is less than the fourth flow rate.

According to this thermal treatment method, the group III nitride semiconductor containing the dopant is treated by using the reducing gas and the nitrogen source gas. In this treatment, the second thermal treatment is performed after the first thermal treatment is performed. In the first thermal treatment, the reducing gas is supplied at the first flow rate of more than zero, and the nitrogen source gas is supplied at the flow rate of not less than zero. Therefore, in this thermal treatment, the contribution by the reducing gas becomes superior to the contribution by the nitrogen source gas, the migration is facilitated in the surface of the group III nitride semiconductor to cause the rearrangement of atoms in the vicinity of the surface. On the other hand, in the second thermal treatment, the nitrogen source gas is supplied at the fourth flow rate of more than zero, and the reducing gas is supplied at the flow rate of not less than zero, and the second flow rate is less than the fourth flow rate. Therefore, in this thermal treatment, the contribution by the nitrogen source gas becomes superior to the contribution by the reducing gas, nitrogen is supplied to the surface of the group III nitride semiconductor to cause the rearrangement of atoms in the vicinity of the surface while the recrystallization is facilitated. In the course of the process of the thermal treatments, the dopant in the group III nitride semiconductor is taken into the site of a crystal lattice to cause the activation of the dopant. Further, alternating the first thermal treatment and the second thermal treatment makes the migration facilitated in the surface of the group III nitride semiconductor, so that the rearrangement of atoms in the vicinity of the surface is further facilitated and the activation of the dopant is further facilitated.

One aspect of the present invention relates to a method of forming a group III nitride semiconductor. This method includes the steps of (a) preparing a group III nitride semiconductor containing at least one of a p-type dopant and an n-type dopant, and (b) performing a treatment of the group III nitride semiconductor by using a reducing gas and a nitrogen source gas to form a conductive group III nitride semiconductor. The treatment includes the step of performing a first thermal treatment of the group III nitride semiconductor while supplying a first treatment gas including the reducing gas having a first flow rate and the nitrogen source gas having a second flow rate to a treatment apparatus, and the step of supplying a second treatment gas including the reducing gas having a third flow rate and the nitrogen source gas having a fourth flow rate to the treatment apparatus to perform a second thermal treatment of the group III nitride semiconductor after the first thermal treatment is performed. In the first thermal treatment, the reducing gas is supplied at the first flow rate, the nitrogen source gas is supplied at the second flow rate, the first flow rate is more than zero, and the second flow rate is not less than zero. In the second thermal treatment, the reducing gas is supplied at the third flow rate, the nitrogen source gas is supplied at the fourth flow rate, the fourth flow rate is more than zero, and the third flow rate is not less than zero. In addition, the second flow rate is less than the fourth flow rate.

According to this method of forming a group III nitride semiconductor, the group III nitride semiconductor containing the dopant is treated by using the reducing gas and the nitrogen source gas. In this treatment, the second thermal treatment is performed after the first thermal treatment has been performed. In the first thermal treatment, the reducing gas is supplied at the first flow rate of more than zero, and the nitrogen source gas is supplied at the second flow rate of not less than zero. Therefore, in this thermal treatment, the contribution by the reducing gas becomes superior to the contribution by the nitrogen source gas, so that the migration is facilitated in the surface of the group III nitride semiconductor and the rearrangement of atoms is caused. On the other hand, in the second thermal treatment, the nitrogen source gas is supplied at the fourth flow rate of more than zero and the reducing gas is supplied at the third flow rate of not less than zero, and the second flow rate is less than the fourth flow rate. Therefore, in this thermal treatment, the contribution by the nitrogen source gas becomes superior to the contribution by the reducing gas, so that nitrogen is supplied to the surface of the group III nitride semiconductor and the rearrangement of atoms is caused while the recrystallization is facilitated. In the course of the process of the thermal treatments, the dopant in the group III nitride semiconductor is taken into the site of the crystal lattice to cause the activation of the dopant. In addition, alternating the first thermal treatment and the second thermal treatment can facilitate the rearrangement of atoms caused by the active migration in the surface of the group III nitride semiconductor and the rearrangement of atoms caused by the supply of nitrogen, and the activation of the dopant is further facilitated.

Another aspect of the present invention relates to a method of fabricating a semiconductor device using a group III nitride semiconductor. This method includes the steps of (a) preparing a group III nitride semiconductor containing at least one of a p-type dopant and an n-type dopant, and (b) performing a treatment of the group III nitride semiconductor by using a reducing gas and a nitrogen source gas to form a conductive group III nitride semiconductor. The treatment includes the step of performing a first thermal treatment of the group III nitride semiconductor while supplying a first treatment gas including the reducing gas having a first flow rate and the nitrogen source gas having a second flow rate to a treatment apparatus, and the step of supplying a second treatment gas including the reducing gas having a third flow rate and the nitrogen source gas having a fourth flow rate to the treatment apparatus to perform a second thermal treatment of the group III nitride semiconductor after the first thermal treatment is performed. In the first thermal treatment, the reducing gas is supplied at the first flow rate, the nitrogen source gas is supplied at the second flow rate, the first flow rate is more than zero, and the second flow rate is not less than zero. In the second thermal treatment, the reducing gas is supplied at the third flow rate, the nitrogen source gas is supplied at the fourth flow rate, the fourth flow rate is more than zero, and the third flow rate is not less than zero. In addition, the second flow rate is less than the fourth flow rate.

According to this method of fabricating a semiconductor device, the group III nitride semiconductor containing the dopant is treated by using the reducing gas and the nitrogen source gas. In this treatment, the second thermal treatment is performed after the first thermal treatment is performed. In the first thermal treatment, the reducing gas is supplied at the first flow rate of more than zero, and the nitrogen source gas is supplied at the second flow rate of not less than zero. Therefore, in this thermal treatment, the contribution by the reducing gas becomes superior to the contribution by the nitrogen source gas, the migration is facilitated in the surface of the group III nitride semiconductor cause the rearrangement of atoms. On the other hand, in the second thermal treatment, the nitrogen source gas is supplied at the fourth flow rate of more than zero, and the reducing gas is supplied at the third flow rate of not less than zero. In addition, the second flow rate is less than the fourth flow rate. Therefore, in this thermal treatment, the contribution by the nitrogen source gas becomes superior to the contribution by the reducing gas and nitrogen is supplied to the surface of the group III nitride semiconductor, so that the rearrangement of atoms is caused while the recrystallization is facilitated. In the course of the process of the thermal treatments, the dopant in the group III nitride semiconductor is taken into the site of the crystal lattice to cause the activation of the dopant. In addition, by alternating the first thermal treatment and the second thermal treatment, the rearrangement of atoms caused by the facilitation of the migration and the rearrangement of atoms while the recrystallization is facilitated are further facilitated, and the activation of the dopant is further facilitated.

In each of the formation, fabrication, and thermal treatment methods according to the present invention (hereinafter referred to as the “method”), the first thermal treatment can be performed at a temperature of not less than 800 degrees Celsius, and the second thermal treatment can be performed at a temperature of not less than 800 degrees Celsius.

According to the above method, the first thermal treatment performed at a temperature of not less than 800 degrees Celsius can facilitate the migration in the surface of the group III nitride semiconductor to cause the rearrangement of atoms. In addition, when the second thermal treatment is performed at a temperature of not less than 800 degrees Celsius, nitrogen supplied to the surface of the group III nitride semiconductor causes the recrystallization of the group III nitride semiconductor while the rearrangement of atoms is facilitated.

In the method according to the aspect of the present invention, the first thermal treatment can be performed at a temperature of not more than 1450 degrees Celsius, and the second thermal treatment can be performed at a temperature of not more than 1450 degrees Celsius.

In the method according to the present invention, the reducing gas of the first thermal treatment can contain at least any of hydrogen (H₂) and hydrochloric acid (HCl), and the reducing gas of the second thermal treatment can contain at least any of hydrogen (H₂) and hydrochloric acid (HCl). According to this method, gases of, e.g., hydrogen (H₂), hydrochloric acid (HCl), and the like can be used as the reducing gas.

In the method according to the aspect of the present invention, the nitrogen source gas of the first thermal treatment can contain at least any of ammonia, a hydrazine-based substance, and an amine-based substance, and the nitrogen source gas of the second thermal treatment can contain at least any of ammonia, the hydrazine-based substance, and the amine-based substance. According to this method, gases of, e.g., ammonia, the hydrazine-based substance, the amine-based substance, and the like can be used as the nitrogen source gas.

In the method according to the aspect of the present invention, the n-type dopant can include at least any of silicon (Si), germanium (Ge), and oxygen (O). According to this method, by the treatment including the first thermal treatment and the second thermal treatment, it is possible to activate the n-type dopants such as silicon (Si), germanium (Ge), and oxygen (O), and impart conductivity to the group III nitride semiconductor.

In the method according to the aspect of the present invention, the p-type dopant can include at least any of magnesium (Mg), calcium (Ca), carbon (C), beryllium (Be), yttrium (Y), and zinc (Zn). According to this method, the treatment including the first thermal treatment and the second thermal treatment enables the activation of the p-type dopant, such as magnesium (Mg), calcium (Ca), carbon (C), beryllium (Be), yttrium (Y), and zinc (Zn), and impart the conductivity to the group III nitride semiconductor.

In the method according to the aspect of the present invention, the treatment can further include the step of performing a third thermal treatment of the group III nitride semiconductor while supplying a third treatment gas including the reducing gas having a fifth flow rate and the nitrogen source gas having a sixth flow rate to the treatment apparatus, and the step of supplying a fourth treatment gas including the reducing gas having a seventh flow rate and the nitrogen source gas having an eighth flow rate to the treatment apparatus to perform a fourth thermal treatment of the group III nitride semiconductor after the third thermal treatment is performed.

According to this method, the third thermal treatment can be performed and may be identical or similar to the first thermal treatment, and the fourth thermal treatment can be performed and may be identical or similar to the second thermal treatment. Thus, by alternately and/or repeatedly performing both the treatment in which the contribution by the reducing gas is superior and the treatment in which the contribution by the nitrogen source gas is superior, the rearrangement of atoms and the recrystallization in the group III nitride semiconductor are facilitated. In the course of the process of the thermal treatments, the dopant in the group III nitride semiconductor is taken into the site of the crystal lattice, and the activation of the dopant is caused.

In the method according to the aspect of the present invention, the nitrogen source gas may not be supplied in the first thermal treatment. According to this method, it is possible to adjust the rearrangement of atoms using the flow rate of the reducing gas.

In the method according to the aspect of the present invention, in the first thermal treatment, when both of the nitrogen source gas and the reducing gas are supplied, it is possible to adjust the rearrangement of atoms in accordance with the ratio between the flow rates of the gases.

In the method according to the aspect of the present invention, the reducing gas may not be supplied in the second thermal treatment. According to this method, it is possible to adjust the rearrangement of atoms using the flow rate of the nitrogen source gas.

In addition, in the second thermal treatment, when both of the nitrogen source gas and the reducing gas are supplied, it is possible to adjust the rearrangement of atoms in accordance with the ratio between the flow rates of the gases.

In the method according to the aspect of the present invention, the group III nitride semiconductor to which the first thermal treatment and the second thermal treatment are applied can include a p-type conductivity region. According to this method, by the application of the first thermal treatment and the second thermal treatment, it is possible to form the p-type conductivity region in the group III nitride semiconductor.

In the method according to the aspect of the present invention, the group III nitride semiconductor to which the first thermal treatment and the second thermal treatment are applied can include an n-type conductivity region. According to this method, the application of the first thermal treatment and the second thermal treatment can form the n-type conductivity region in the group III nitride semiconductor.

In the method according to the aspect of the present invention, the group III nitride semiconductor to which the first thermal treatment and the second thermal treatment are applied can include both of the p-type dopant and the n-type dopant. According to this method, the application of the first thermal treatment and the second thermal treatment can activate both of the p-type dopant and the n-type dopant coexisting in the group III nitride semiconductor.

In the method according to the aspect of the present invention, the group III nitride semiconductor to which the first thermal treatment and the second thermal treatment are applied can include a first portion and a second portion, the first portion of the group III nitride semiconductor can exhibit an n-type conductivity, and the second portion of the group III nitride semiconductor can exhibit a p-type conductivity. According to this method, the application of the first thermal treatment and the second thermal treatment can form the first portion having the n-type conductivity and the second portion having the p-type conductivity that are provided in the group III nitride semiconductor by the activation.

In the method according to the aspect of the present invention, the step of preparing the group III nitride semiconductor may include the step of growing a group III nitride semiconductor layer while supplying the dopant and a material gas to a growth reactor. According to this method, it is possible to activate the dopant taken into the group III nitride semiconductor layer during the film formation in the growth reactor.

In the method according to the aspect of the present invention, the material gas can contain an organometallic material, and the dopant can include the p-type dopant. According to this method, it is possible to activate the p-type dopant taken into the group III nitride semiconductor during the film formation using the material gas containing the organometallic material. In addition, the material gas can contain the organometallic material, and the dopant can include the n-type dopant.

The method according to the aspect of the present invention can further include the step of growing a group III nitride semiconductor layer in a growth reactor. The step of preparing the group III nitride semiconductor can include the step of ion-implanting the dopant into the group III nitride semiconductor layer to form the group III nitride semiconductor. According to this method, it is possible to activate the dopant ion-implanted into the group III nitride semiconductor after the film formation.

The method according to the aspect of the present invention can further include the step of forming a mask having a pattern on the group III nitride semiconductor layer after the group III nitride semiconductor layer is grown. The step of preparing the group III nitride semiconductor can include the step of ion-implanting the dopant into the group III nitride semiconductor layer by using the mask to form the group III nitride semiconductor. According to this method, it is possible to limit the implantation region of the dopant and introduce the dopant by the ion implantation method.

In the method according to the aspect of the present invention, the conductive group III nitride semiconductor can include a first region and a second region that are disposed successively from a surface of the group III nitride semiconductor in a depth direction, the conductive group III nitride semiconductor can have a p-type dopant profile and an n-type dopant profile that are defined from the surface of the group III nitride semiconductor in the depth direction, an n-type dopant concentration in the n-type dopant profile can be higher than a p-type dopant concentration in the p-type dopant profile in the first region of the conductive group III nitride semiconductor, and the p-type dopant concentration in the p-type dopant profile can be higher than the n-type dopant concentration in the n-type dopant profile in the second region of the conductive group III nitride semiconductor.

According to this method, it is possible to provide the first region and the second region, disposed successively from the surface of the group III nitride semiconductor in the depth direction, with the first and second conductivities different from each other.

In the method according to the aspect of the present invention, the conductive group III nitride semiconductor can include a first region and a second region that are disposed successively from a surface of the group III nitride semiconductor in a depth direction, the conductive group III nitride semiconductor can have a p-type dopant profile and an n-type dopant profile that are defined from the surface of the group III nitride semiconductor in the depth direction, a p-type dopant concentration in the p-type dopant profile can be higher than an n-type dopant concentration in the n-type dopant profile in the first region of the conductive group III nitride semiconductor, and the n-type dopant concentration in the n-type dopant profile can be higher than the p-type dopant concentration in the p-type dopant profile in the second region of the conductive group III nitride semiconductor.

In the method according to the present invention, the group III nitride semiconductor can include at least any of GaN, InN, AlN, AlGaN, InGaN, InAlN, and InAlGaN. This method can allow for the rearrangement of atoms and the recrystallization in the group III nitride semiconductor such as GaN, InN, AlN, AlGaN, InGaN, InAlN, or InAlGaN.

The method according to the aspect of the present invention can further include the step of growing a group III nitride semiconductor layer in a growth reactor. The step of preparing the group III nitride semiconductor can include the step of ion-implanting the dopant into the group III nitride semiconductor layer once or a plurality of times to form the group III nitride semiconductor, and the ion implantation can be performed the plurality of times by using different acceleration energies. According to this method, the utilization of the ion implantation performed once or the plurality of times can provide the group III nitride semiconductor layer for the semiconductor device with the desired dopant profile.

The method according to the present invention can further include the step of forming a mask having a pattern on the group III nitride semiconductor layer after the group III nitride semiconductor layer is grown. The step of preparing the group III nitride semiconductor can include the step of ion-implanting the dopant into the group III nitride semiconductor layer by using the mask to form the group III nitride semiconductor layer. According to this method, using the mask can introduce the dopant with the desire pattern in terms of the position.

The method according to the aspect of the present invention can further include the steps of growing a mask film formed of an insulating material different from the material of the group III nitride semiconductor layer before the mask is formed, and forming a resist mask formed in a pattern on the mask film. The mask can be formed by etching the mask by using the resist mask in the step of forming the mask. According to this method, since the mask film is used, the ion implantation with high energy can be applied.

In the method according to the aspect of the present invention, a surface of the group III nitride semiconductor layer can be formed of GaN or AlGaN, and the mask can be formed of a group III nitride different from a material of the surface of the group III nitride semiconductor layer. According to this method, it is possible to use the group III nitride as the mask film.

In the method according to the aspect of the present invention, the mask can include an AlN layer or AlGaN having a different composition. According to this method, the group III nitrides such as AlN and AlGaN can be used as the mask film. Note that SiN or SiO₂ can also be used as a matter of course.

The method according to the present invention can further include the step of removing the mask after the treatment of the group III nitride semiconductor is performed to expose a surface of the group III nitride semiconductor layer.

According to this method, since the mask is formed of the group III nitride semiconductor different from that of the group III nitride semiconductor layer, the mask can be removed after the ion implantation to expose the surface of the group III nitride semiconductor layer. In the treatment of the group III nitride semiconductor layer, the surface appearing in the opening of the mask is exposed to the reducing gas and the nitrogen source gas to cause the rearrangement of atoms and the recrystallization therein.

The method according to the aspect of the present invention can further include the step of removing the mask before the treatment of the group III nitride semiconductor is performed to expose a surface of the group III nitride semiconductor layer. According to this fabrication method, since the mask is formed of the group III nitride semiconductor different from that of the group III nitride semiconductor layer, the mask can be removed after the ion implantation to expose the surface of the group III nitride semiconductor layer. In the treatment of the group III nitride semiconductor layer, the exposed surface is applied to the reducing gas and the nitrogen source gas to cause the rearrangement of atoms and the recrystallization.

In the method according to the aspect of the present invention, in the removal in a case where the group III nitride such as MN or AlGaN is used as the mask film, an alkaline aqueous solution can be used. As the alkaline aqueous solution, it is possible to use, e.g., aqueous ammonia and tetramethyl ammonium hydroxide. According to this method, the group III nitride semiconductor is subjected to wet etching by using the alkaline aqueous solution, e.g., aqueous ammonia or tetramethyl ammonium hydroxide. Note that, in a case where SiN or SiO₂ is used, hydrofluoric acid or buffered hydrofluoric acid can be used for the removal.

In the method according to the present invention, a surface of the conductive group III nitride semiconductor to which the first thermal treatment and the second thermal treatment are applied can include a p-type conductivity region and an n-type conductivity region formed.

This method can fabricate the semiconductor device in which the surface of the conductive group III nitride semiconductor includes the p-type conductivity region and the n-type conductivity region.

In the method according to the aspect of the present invention, the semiconductor device can include a Schottky diode, and the conductive group III nitride semiconductor can include a p-type guard ring of the Schottky diode. This method can form the p-type region and a pn junction for the p-type guard ring of the semiconductor device.

The method according to the aspect of the present invention can further include the step of forming a Schottky electrode such that the Schottky electrode is in contact with the conductive group III nitride semiconductor. According to this method, the Schottky electrode is in contact with the semiconductor region having the excellent p-type conductivity, and hence can improve the breakdown voltage of the Schottky electrode.

In the method according to the aspect of the present invention, the semiconductor device can include a transistor, and the conductive group III nitride semiconductor can include a p-type well of the transistor. This method can form the p-type region for the well of the semiconductor device.

In the method according to the aspect of the present invention, the conductive group III nitride semiconductor can include a first region and a second region that are disposed successively from a surface of the group III nitride semiconductor in a depth direction, the conductive group III nitride semiconductor can have a first conductivity type dopant profile and a second conductivity type dopant profile that are defined from the surface of the group III nitride semiconductor in the depth direction, a first conductivity type dopant concentration in the first conductivity type dopant profile can be higher than a second conductivity type dopant concentration in the second conductivity type dopant profile in the first region of the conductive group III nitride semiconductor, and the second conductivity type dopant concentration in the second conductivity type dopant profile can be higher than the first conductivity type dopant concentration in the first conductivity type dopant profile in the second region of the conductive group III nitride semiconductor.

According to this method, the conductive group III nitride semiconductor has the p-type dopant profile and the n-type dopant profile, which are defined in the depth direction from the surface of the group III nitride semiconductor, and can provide this structure to fabricate the semiconductor device that requires a complicated dopant profile.

In the method according to the aspect of the present invention, the first conductivity type dopant profile can be an n-type dopant profile, the second conductivity type dopant profile can be a p-type dopant profile, the conductive group III nitride semiconductor can include a third region that extends from the second region and reaches the surface of the group III nitride semiconductor so as to surround the first region, the first region can include a source region of the transistor, and the second region and the third region can include a well region of the transistor.

According to this method, the source region of the transistor and the well region of the transistor can be provided with the first region and the second region.

The method according to the aspect of the present invention can further include the step of forming an electrode such that the electrode is in contact with the well region and the source region. According to this method, the electrode can be brought into contact with the source and the well both having excellent conductivity.

The method according to the aspect of the present invention can further include the steps of forming a gate film on the well region, and forming a gate electrode on the gate film. This method can provide both the first region that can include the source region of the transistor, and the second region that can include the well region of the transistor.

In the method according to the aspect of the present invention, the semiconductor device can include a junction diode, the conductive group III nitride semiconductor can include a first region and a second region that are disposed successively from a surface of the group III nitride semiconductor in a depth direction, the group III nitride semiconductor can have a p-type dopant profile and an n-type dopant profile that are defined from the surface of the group III nitride semiconductor in the depth direction, a p-type dopant concentration in the p-type dopant profile can be higher than an n-type dopant concentration in the n-type dopant profile in the first region of the group III nitride semiconductor, and the n-type dopant concentration in the n-type dopant profile can be higher than the p-type dopant concentration in the p-type dopant profile in the second region of the group III nitride semiconductor. The method can further include the step of forming an electrode in contact with the first region of the conductive group III nitride semiconductor. This method can provide the first region that can include a cathode region of the junction diode and the second region that can include an anode region of the junction diode.

In the method according to the aspect of the present invention, the first region and the second region of the conductive group III nitride semiconductor can constitute a pn junction for the junction diode. This method can provide the semiconductor device that can include the excellent pn junction for the junction diode.

In the method according to the aspect of the present invention, the conductive group III nitride semiconductor can include an i-type region provided between the first region and the second region, and the first region, the i-type region, and the second region can constitute a pin junction for the junction diode. According to this method, the semiconductor device can include the pin junction for the junction diode.

The method according to the aspect of the present invention can further include the steps of preparing a conductive substrate having a primary surface and a back surface, and forming a back surface electrode on the back surface of the conductive substrate after the conductive group III nitride semiconductor is formed. The step of preparing the group III nitride semiconductor can include the step of forming the group III nitride semiconductor on the primary surface of the conductive substrate such that at least one of the p-type dopant and the n-type dopant is contained. This method can provide the semiconductor device that can have a vertical structure.

The method according to the aspect of the present invention can further include the steps of performing observation of a surface of the group III nitride semiconductor after the treatment using the reducing gas and the nitrogen source gas is performed, and determining that a subsequent treatment in the method of fabricating a semiconductor device is applied when a morphology appears on the surface of the group III nitride semiconductor in the observation. According to this method, since a determination can be made as to whether or not the morphology is created in the surface of the group III nitride semiconductor after the thermal treatment, the appearance of the morphology can provide information on the presence or absence of the excellent atom rearrangement and the recrystallization.

The method according to the aspect of the present invention can further include the step of forming an electrode on the conductive group III nitride semiconductor after the determination. According to this method, since a determination can be made as to whether or not the morphology is created in the surface of the group III nitride semiconductor after the thermal treatment, the appearance of the morphology can provide information on the formation of the electrode on the conductive group III nitride semiconductor as the result of the excellent atom rearrangement and the recrystallization.

In the method according to the aspect of the present invention, the step of preparing the group III nitride semiconductor can include any of regrowth and burying growth of the group III nitride semiconductor. According to this method, the group III nitride semiconductor containing the dopant can be formed by various growth methods.

A group III nitride semiconductor device according to yet another aspect of the present invention includes a group III nitride semiconductor region. A p-type dopant is selectively implanted into a portion of the group III nitride semiconductor region, and the implanted p-type dopant is activated by any of the thermal treatment methods described above.

A group III nitride semiconductor device according to yet another aspect of the present invention includes a Schottky barrier diode having a p-type guard ring, and a p-type dopant of the p-type guard ring is activated by any of the thermal treatment methods described above.

A group III nitride semiconductor device according to yet another aspect of the present invention includes a vertical transistor having a p-type semiconductor layer and an n-type semiconductor layer, and a dopant of each of the p-type semiconductor layer and the n-type semiconductor layer is activated by any of the thermal treatment methods described above.

A group III nitride semiconductor device according to yet another aspect of the present invention includes a group III nitride semiconductor region having a first portion and a second portion, the first portion of the group III nitride semiconductor region is selectively ion-implanted with the p-type dopant, e.g., Mg, and the second portion of the group III nitride semiconductor region is not ion-implanted. The implanted p-type dopant, e.g., Mg is activated, and a surface of the first portion has a surface morphology different from that of a surface of the second portion.

A group III nitride semiconductor device according to yet another aspect of the present invention includes a Schottky barrier diode having a p-type guard ring layer and an n-type semiconductor region, a p-type dopant of the p-type guard ring layer is activated, and at least a portion of a surface of the p-type guard ring layer has a surface morphology different from that of the n-type semiconductor region.

A group III nitride semiconductor device according to yet another aspect of the present invention includes a vertical transistor having a p-type semiconductor layer and an n-type contact layer, a dopant of each of the p-type semiconductor layer and the n-type semiconductor layer is activated, and at least a portion of a surface of any of the p-type semiconductor layer and the n-type semiconductor layer has a surface morphology different from that of the other portion thereof.

The above and other objects, features, and advantages of the present invention will become apparent easily from the following detailed description of preferred embodiments of the present invention given in conjunction with the accompanying drawings.

### BRIEF DESCRIPTION OF THE DRAWINGS

FIG. 1 is a view showing a process flow including major steps in a method of forming a group III nitride semiconductor, a method of fabricating a semiconductor device, and a method of performing a thermal treatment of a group III nitride semiconductor according to the present embodiment;

FIG. 2 is a view showing the process flow including major steps in the method of forming a group III nitride semiconductor, the method of fabricating a semiconductor device, and the method of performing a thermal treatment of a group III nitride semiconductor according to the present embodiment;

FIG. 3 is a view schematically showing the major steps in the method of forming a group III nitride semiconductor, the method of fabricating a semiconductor device, and the method of performing a thermal treatment of a group III nitride semiconductor according to the present embodiment;

FIG. 4 is a view schematically showing the major steps in the method of forming a group III nitride semiconductor, the method of fabricating a semiconductor device, and the method of performing a thermal treatment of a group III nitride semiconductor according to the present embodiment;

FIG. 5 is a view schematically showing the major steps in the method of forming a group III nitride semiconductor, the method of fabricating a semiconductor device, and the method of performing a thermal treatment of a group III nitride semiconductor according to the present embodiment;

FIG. 6 is a view showing an n-type dopant profile and a p-type dopant profile in a conductive group III nitride semiconductor;

FIG. 7 is a view showing the structure of a semiconductor device including a Schottky electrode;

FIG. 8 is a view showing the structure of a vertical transistor including an ohmic electrode;

FIG. 9 is a view showing the structure of a junction diode including the ohmic electrode;

FIG. 10 is a view showing a list according to Example 1;

FIG. 11 is a view showing a list according to Example 2;

FIG. 12 is a view showing a list according to Example 3;

FIG. 13 is a view showing a list according to Example 4;

FIG. 14 is a view showing a list according to Example 5;

FIG. 15 is a view showing a process flow in a method of fabricating a Schottky barrier diode according to Example 6;

FIG. 16 is a view showing the structure of the Schottky barrier diode according to Example 6;

FIG. 17 is a view showing characteristics of the Schottky barrier diode according to Example 6;

FIG. 18 is a view showing a process flow in a method of fabricating a vertical transistor according to Example 7;

FIG. 19 is a view showing the process flow in the method of fabricating the vertical transistor according to Example 7;

FIG. 20 is a view showing the structure of the vertical transistor according to Example 7;

FIG. 21 is a view showing characteristics of the vertical transistor according to Example 7;

FIG. 22 is a view showing a differential interference microscope image of the appearance of an epitaxial surface processed in H2/NH3 annealing; and

FIG. 23 is a view showing a differential interference microscope image of the appearance of the epitaxial surface processed in H2/NH3 annealing.

### DESCRIPTION OF THE PREFERRED EMBODIMENTS

A description will be given of an embodiment of the present invention related to a method of forming a group III nitride semiconductor, a method of fabricating a semiconductor device, a method of performing a thermal treatment of a group III nitride semiconductor, and a group III nitride semiconductor device with reference to the accompanying drawings. If possible, the same portions are denoted by the same reference symbols.

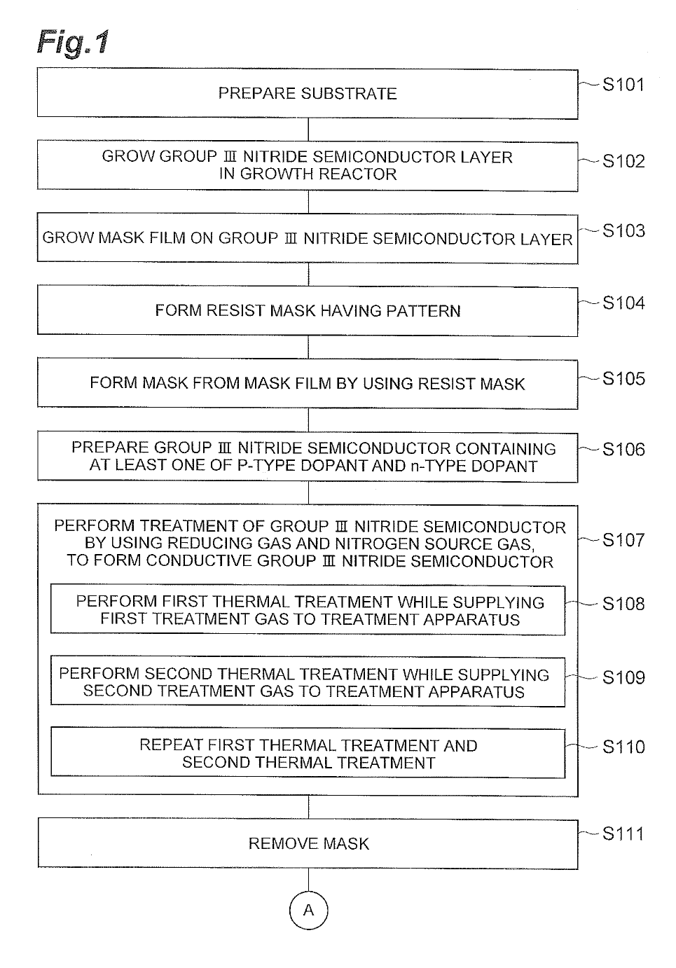

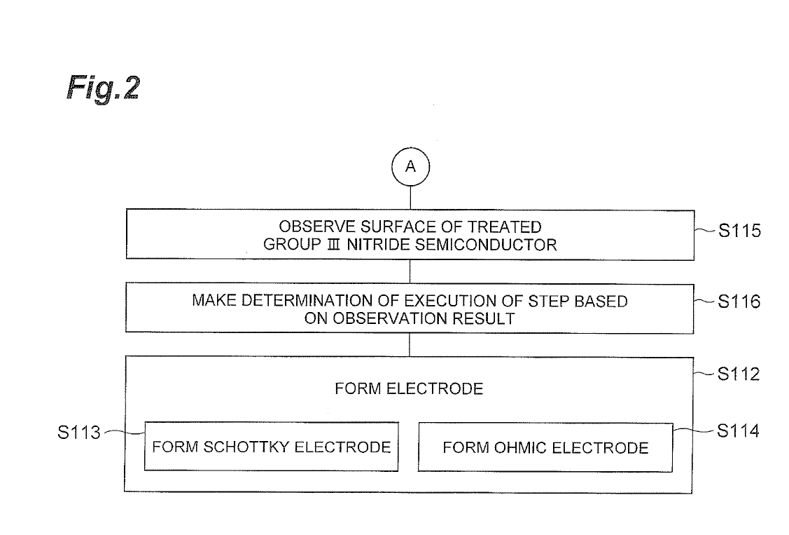

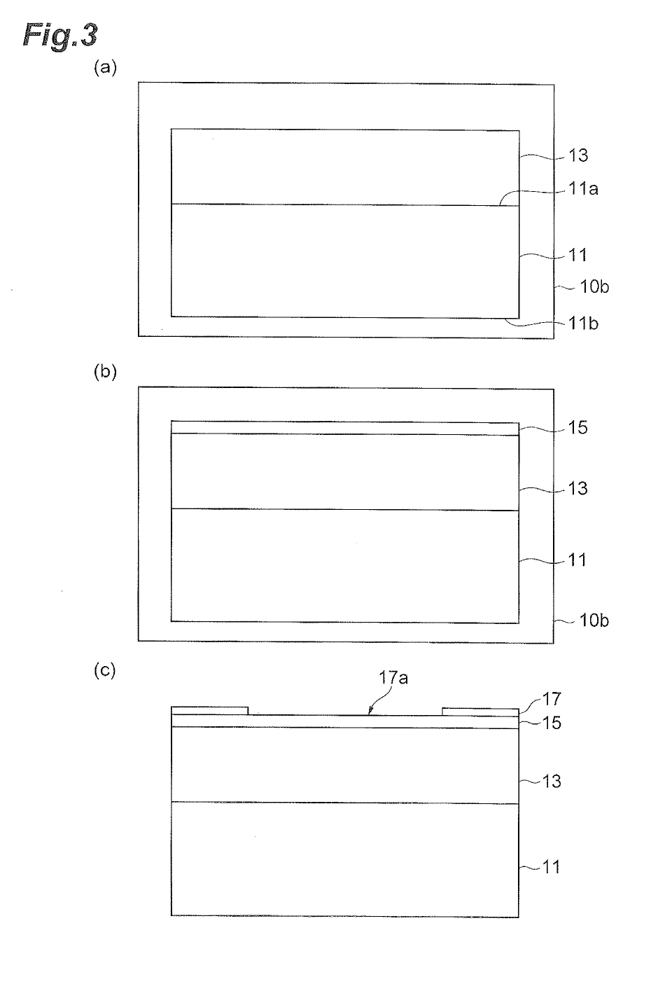

FIGS. 1 and 2 show views each showing a process flow including major steps in a method of forming a group III nitride semiconductor, a method of fabricating a semiconductor device, and a method of performing a thermal treatment of a group III nitride semiconductor according to the present embodiment. FIGS. 3 to 5 show schematic views of the major steps in the method of forming a group III nitride semiconductor, the method of fabricating a semiconductor device, and the method of performing a thermal treatment of a group III nitride semiconductor according to the present embodiment.

In Step S101, a substrate is prepared. The substrate can have conductivity. As shown in Part (a) of FIG. 3, a substrate 11 has a primary surface 11a and a back surface 11b. The conductivity of the substrate 11 is useful for the fabrication of a semiconductor vertical device. The substrate 11 can be a plate-like article such as, e.g., a wafer or the like. The wafer is preferably formed of GaN, but can also be formed of materials such as Si and SiC.

In Step S102, as shown in Part (a) of FIG. 3, a group III nitride semiconductor layer 13 is grown on the primary surface 11a of the substrate 11 in a growth reactor 10a. Film forming methods such as, e.g., a metal organic vapor phase epitaxy method, MBE method, HYPE method, and PLD method can be used for the growth of the group III nitride semiconductor layer 13.

If necessary, it is possible to form a mask that allows the selective introduction of dopant in terms of its position, and also perform ion implantation through the mask. However, it is possible to perform the ion implantation on the entire surface of the substrate without using the mask. In addition, if necessary, it is possible to grow the group III nitride semiconductor layer on the substrate 11 such that the group III nitride semiconductor layer contains the dopant.

In Step S103, as shown in Part (b) of FIG. 3, a mask film 15 is grown in a growth reactor 10b. The mask film 15 is formed of a material different from that of the group III nitride semiconductor layer 13 (e.g., an insulating material). The mask film 15 can be formed of materials such as, e.g., AlN, AlGaN, SiN, and SiO₂. For the growth of the mask film 15, methods such as the metal organic vapor phase epitaxy method, MBE method, sputtering method, and EB deposition can be used for, e.g., AlN and AlGaN, and film forming methods such as a plasma CVD method, sputtering method, thermal CVD method, and EB deposition can be used for SiN and SiO₂. When the mask film 15 formed of the group III nitride semiconductor is used, it is possible to use high energy ion implantation.

In Step S104, as shown in Part (c) of FIG. 3, a resist mask 17 having a pattern is formed on the mask film 15. The resist mask 17 can have, e.g., an opening 17a.

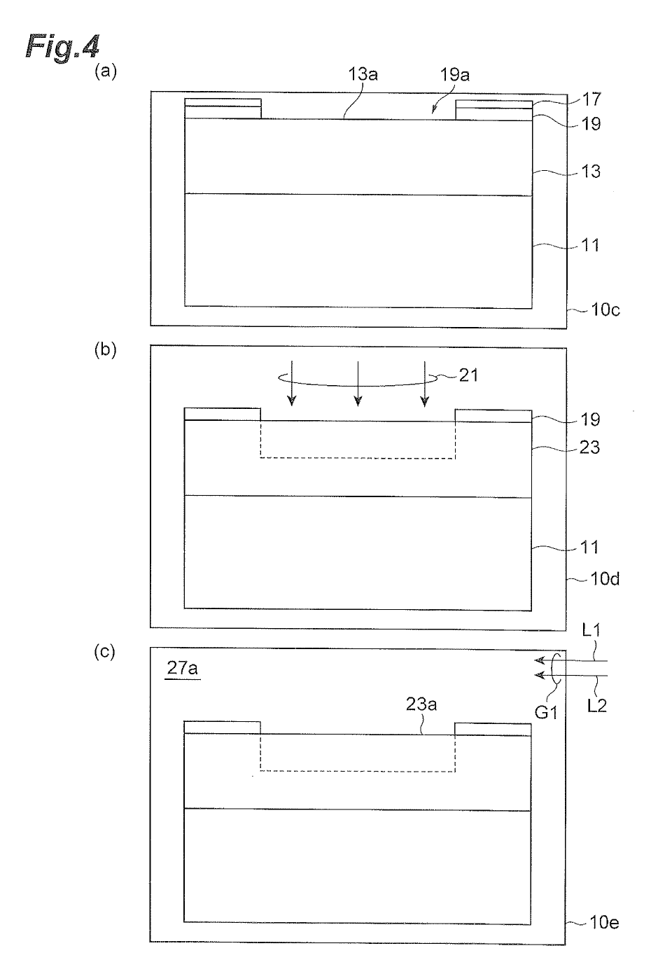

In Step S105, as shown in Part (a) of FIG. 4, the mask film 15 is etched by an etching apparatus 10c by using the resist mask 17, and a mask 19 for ion implantation is formed. The mask 19 has a pattern that allows specifying the location of ion implantation. The mask 19 has, e.g., an opening 19a, and a surface 13a of the group III nitride semiconductor layer 13 is exposed in the opening 19a. In this step, the mask 19 is formed on the group III nitride semiconductor layer 13. According to this method, it is possible to define a region to implant dopant ions and introduce the dopant by an ion implantation method. Note that, if possible, it is possible to use the resist mask as the ion implantation mask without using the mask film 15.

In Step S106, as shown in (b) of FIG. 4, a group III nitride semiconductor 23 containing at least one of a p-type dopant 21 and an n-type dopant 21 is prepared. The preparation can be made by the introduction of the dopant 21 using ion implantation. In this step, it is possible to form the group III nitride semiconductor 23 by, e.g., ion-implanting the dopant 21 into the group III nitride semiconductor layer 13 by using the mask 19. In addition, with regard to the introduction of the dopant 21, one or more ion implantations may be performed by using an ion implantation apparatus 10d, and it is thereby possible to form the group III nitride semiconductor 23. different acceleration energies and/or different doses can be applied to the plural ion implantations. According to this method, by the utilization of the ion implantations performed a number of times, it is possible to form a desired dopant profile in the group III nitride semiconductor 23 for a semiconductor device.

As described above, the preparation of the group III nitride semiconductor containing the dopant 21, i.e., at least one of the p-type dopant and the n-type dopant can be performed by the ion implantation of the dopant 21. However, the method is not limited to the introduction of the dopant by the ion implantation. In Step S106, it is possible to grow the group III nitride semiconductor layer on the primary surface 11a of the substrate 11 while supplying, e.g., a dopant gas and a material gas to the growth reactor (e.g., the growth reactor 10a). According to this method, it is possible to activate the dopant taken into the group III nitride semiconductor layer during the film formation in the growth reactor.

The material gas preferably contains an organometallic material, and the dopant gas preferably contains a substance for the p-type dopant (e.g., Cp₂Mg and EtCp₂Mg). This method allows the activation of the p-type dopant taken into the group III nitride semiconductor during the film formation using the material gas containing the organometallic material. Alternatively, the group III nitride semiconductor layer may be grown on the primary surface 11a of the substrate 11 such that at least one of the p-type dopant and the n-type dopant is contained. In addition, the group III nitride semiconductor layer may be grown on the primary surface 11a of the substrate 11 such that the n-type dopant is contained. The growth of the group III nitride semiconductor includes re-growing or growing for burying. According to this method, the group III nitride semiconductor containing the dopant can be formed using various growth methods.

The group III nitride semiconductor to be grown or subjected to the ion implantation includes at least any of GaN, InN, AlN, AlGaN, InGaN, InAlN, and InAlGaN. According to this method, it is possible to cause rearrangement of atoms and recrystallization in the group III nitride semiconductor such as GaₛAl_{T}In_{1-S-T}N (0≦S≦1, 0≦T≦1).

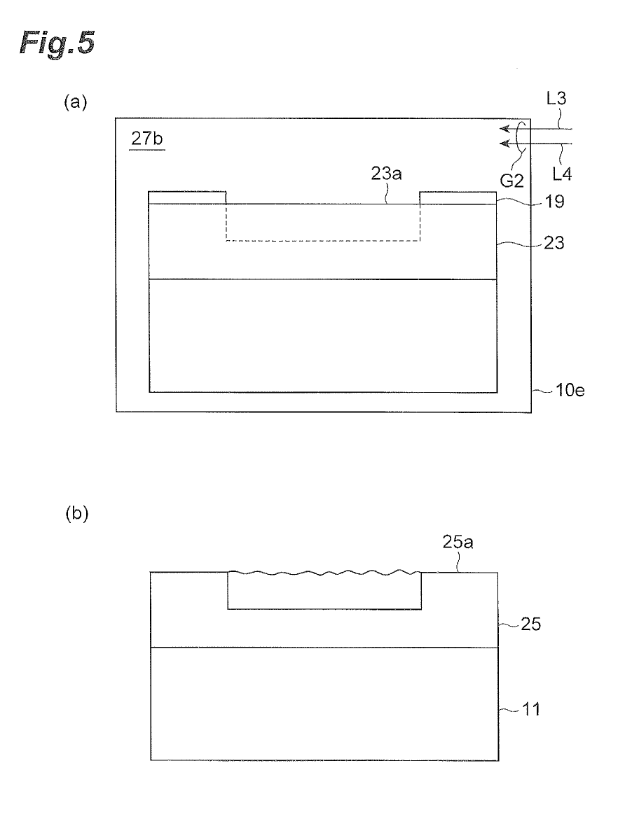

In Step S107, as shown in Part (c) of FIG. 4, Part (a) of FIG. 5, and Part (b) of FIG. 5, a treatment using a reducing gas and a nitrogen source gas is performed on the group III nitride semiconductor 23, thereby forming a conductive group III nitride semiconductor 25. The treatment can include a first thermal treatment 27a and a second thermal treatment 27b.

In Step S108, the first thermal treatment 27a is performed. In the first thermal treatment 27a, the thermal treatment of the group III nitride semiconductor 23 is performed using a first treatment gas (process gas) G1, and during the thermal treatment, the reducing gas and the nitrogen source gas of the first treatment gas (process gas) G1 including are supplied to a treatment apparatus 10e at a first flow rate L1 and a second flow rate L2, respectively. In the first thermal treatment 27a, the reducing gas is supplied at the first flow rate L1, while the nitrogen source gas is supplied at the second flow rate L2. In the first thermal treatment 27a, the first flow rate L1 is more than zero (L1>0). The second flow rate L2 is not less than zero. The second flow rate L2 preferably has a value less than that of the first flow rate (less than L1) (0≦L2<L1). In addition, the time period of the first thermal treatment 27a can be set to, e.g., not less than 0.1 seconds and, if the time period thereof is less than 0.1 seconds, it is not possible to facilitate sufficient migration (with regard to the facilitation of the migration, the migration is considered to be facilitated by removing nitrogen in the uppermost surface of GaN using the reducing gas and having only the uppermost surface of GaN made of Ga). The time period of the first thermal treatment 27a can be set to, e.g., not more than 5 seconds and, if the time period thereof is excessively long, not only the migration but also nitrogen dissociation by the reducing gas is excessive, resulting in complete decomposition of crystal.

In Step S109, after the first thermal treatment 27a has been performed, the second thermal treatment 27b is performed. In the second thermal treatment 27b, the thermal treatment of the group III nitride semiconductor 23 is performed using a second treatment gas (process gas) G2, and during the second thermal treatment 27b, the reducing gas and the nitrogen source gas of the second treatment gas (process gas) G2 are supplied to the treatment apparatus 10e at a third flow rate L3 and a fourth flow rate L4, respectively. In the second thermal treatment 27b, the reducing gas is supplied at the third flow rate L3, while the nitrogen source gas is supplied at the fourth flow rate L4. In the second thermal treatment 27b, the fourth flow rate L4 is more than zero, and the third flow rate L3 is not less than zero. The third flow rate L3 preferably has a value not more than that of the fourth flow rate (not more than L4) (0≦L3≦L4). As the treatment apparatus 10e, it is possible to use, e.g., an RTA or an epitaxial apparatus (e.g., a metal organic vapor phase epitaxy apparatus). In addition, the time period of the second thermal treatment 27b can be set to, e.g., not less than 0.01 seconds, and in the time period thereof that is less than 0.01 seconds, recrystallization, i.e., recrystallization to GaN caused by the reaction between nitrogen and Ga at the uppermost surface becomes insufficient. The time period of the second thermal treatment 27b can be set to, e.g., not more than 10 seconds, the purpose of the second thermal treatment 27b is the recrystallization, i.e., turning Ga in the uppermost surface into GaN, and the recrystallization is not influenced even when the treatment time period is longer.

According to this method, the group III nitride semiconductor 23 containing the dopant is treated by using the reducing gas and the nitrogen source gas. In this treatment, the second thermal treatment (Step S109) 27b is performed after the first thermal treatment (Step S108) 27a is performed. In the first thermal treatment (Step S108) 27a, the reducing gas is supplied at the first flow rate L1 of more than zero, and the nitrogen source gas is supplied at the second flow rate L2 of not less than zero. Consequently, in the thermal treatment (Step S108) 27a, the contribution by the reducing gas becomes superior to the contribution by the nitrogen source gas, the migration is facilitated around the surface of the group III nitride semiconductor 23 to cause the rearrangement of atoms in the vicinity of the surface thereof and in the internal portion thereof. On the other hand, in the second thermal treatment (Step S109) 27b, the nitrogen source gas is supplied at the fourth flow rate L4 of more than zero, and the reducing gas is supplied at the third flow rate L3 of not less than zero. Consequently, in this thermal treatment (Step S109) 27b, the contribution by the nitrogen source gas becomes superior to the contribution by the reducing gas, nitrogen is supplied to the surface 23a of the group III nitride semiconductor 23, resulting in that the rearrangement of atoms in the vicinity of the surface thereof and in the internal portion thereof is caused while the recrystallization is facilitated. In the course of the process of the thermal treatments, the dopant in the group III nitride semiconductor 23 is taken into sites in the crystal lattice, and the activation of the dopant is caused.

The n-type dopant can include at least any of silicon (Si), germanium (Ge), and oxygen (O). According to this method, the treatment including the first thermal treatment 27a and the second thermal treatment 27b makes it possible to activate the n-type dopant such as silicon (Si), germanium (Ge), or oxygen (O), and provide the group III nitride semiconductor with electrical conductivity.

The p-type dopant can include at least any of magnesium (Mg), calcium (Ca), carbon (C), beryllium (Be), yttrium (Y), and zinc (Zn). According to this method, the treatment including the first thermal treatment 27a and the second thermal treatment 27b makes it possible to activate the p-type dopant such as magnesium (Mg), calcium (Ca), carbon (C), beryllium (Be), yttrium (Y), or zinc (Zn) to provide the group III nitride semiconductor with electrical conductivity.

In the treatment is Step S110, one thermal treatment such as the first thermal treatment 27a and another thermal treatment such as the second thermal treatment 27b can be repeated. The number of times of the repetition can range from about 2 to 1000. This treatment can include, e.g., a third thermal treatment and a fourth thermal treatment. In Step S110, it is possible to perform the third thermal treatment of the group III nitride semiconductor while supplying a third treatment gas to the treatment apparatus. The third treatment gas includes the reducing gas and the nitrogen source gas, which are supplied at a sixth flow rate and a sixth flow rate, respectively. In addition, in Step S110, after the third thermal treatment is performed, the fourth treatment gas is supplied to the treatment apparatus, and it is possible to perform the fourth thermal treatment of the group III nitride semiconductor. The fourth treatment gas includes the reducing gas and the nitrogen source gas, which are supplied at a seventh flow rate and an eighth flow rate, respectively.

According to this method, it is possible to perform the third thermal treatment identical or similar to the first thermal treatment 27a, and perform the fourth thermal treatment identical or similar to the second thermal treatment 27b. Thus, the rearrangement of atoms and the recrystallization of the group III nitride semiconductor are facilitated by alternately performing the treatment in which the contribution by the reducing gas is superior and the treatment in which the contribution by the nitrogen source gas is superior. In the course of the process of the thermal treatments, the dopant in the group III nitride semiconductor is taken into sites in the crystal lattice, resulting in the activation of the dopant.

More specifically, in the treatment in Step S110, after the third thermal treatment is performed, the fourth thermal treatment is performed. In the third thermal treatment, the reducing gas is supplied at a fifth flow rate L5 of more than zero, and the nitrogen source gas is supplied at a sixth flow rate L6 of not less than zero. Consequently, in this thermal treatment, the contribution by the reducing gas becomes superior to the contribution by the nitrogen source gas, so that the migration is facilitated in the surface of the group III nitride semiconductor, and the rearrangement of atoms in not only the vicinity of the surface thereof but also the internal portion thereof is caused. On the other hand, in the fourth thermal treatment, the nitrogen source gas is supplied at an eighth flow rate L8 of more than zero, and the reducing gas is supplied at a seventh flow rate L7 of not less than zero. Consequently, in this thermal treatment, the contribution by the nitrogen source gas becomes superior to the contribution by the reducing gas, and nitrogen is supplied to the surface of the group III nitride semiconductor, so that the rearrangement of atoms in the vicinity of the surface thereof and in the internal portion thereof is caused while the recrystallization is facilitated.

For example, the supply of the nitrogen source gas may be stopped in the first thermal treatment (S108) 27a. According to this method, adjusting the flow rate of the reducing gas can control the degrees of the rearrangement of atoms. The first flow rate L1 depends on, e.g., the size of the apparatus, and it can be set to not less than 1 SLM and not more than 100 SLM. The supply of the reducing gas may be stopped in the second thermal treatment (S109) 27b. According to this method, adjusting the flow rate of the nitrogen source gas can control the rearrangement of atoms. The fourth flow rate L4 depends on, e.g., the size of the apparatus, and it can be set to not less than 1 SLM and not more than 100 SLM.

In addition, in the first thermal treatment (S108) 27a, the first flow rate L1 can be set to more than zero, and the second flow rate L2 can be set to more than zero. When both of the nitrogen source gas and the reducing gas are supplied in the first thermal treatment (S108) 27a, the rearrangement of atoms can be changed in accordance with the ratio between the flow rates of the gases. The first flow rate L1 depends on, e.g., the size of the apparatus or the temperature, and it can be set to not less than 1 SLM and not more than 100 SLM. The second flow rate L2 depends on, e.g., the size of the apparatus or the temperature, and it can be set to not less than 0 SLM and not more than 10 SLM.

In the second thermal treatment (S109) 27b, the fourth flow rate L4 can be set to more than zero, and the third flow rate L3 can be set to more than zero. When both of the nitrogen source gas and the reducing gas are supplied in the second thermal treatment (S109) 27b, the recrystallization of atoms can be changed in accordance with the ratio between the flow rates of the gases. The third flow rate L3 depends on, e.g., the size of the apparatus or the temperature, and it can be set to not less than 1 SLM and not more than 100 SLM. The fourth flow rate L4 depends on, e.g., the size of the apparatus or the temperature, and it can be set to not less than 1 SLM and not more than 100 SLM.

It is possible to perform the first thermal treatment 27a at a temperature of not less than 800 degrees Celsius. In this temperature range, the migration is facilitated in the surface of the group III nitride semiconductor, and the rearrangement of atoms is caused in the group III nitride semiconductor. In addition, it is possible to perform the second thermal treatment 27b at a temperature of not less than 800 degrees Celsius. In this temperature range, nitrogen is supplied to the surface of the group III nitride semiconductor, so that the recrystallization of the group III nitride semiconductor is caused while the rearrangement of atoms is facilitated.

It is possible to perform the first thermal treatment 27a at a temperature of not more than 1450 degrees Celsius. In this temperature range, when the temperature is excessively high, the activation of the p-type dopant such as Mg or the like may become insufficient. In addition, when the temperature is excessively high, the group III nitride semiconductor may be severely etched. Further, it is possible to perform the second thermal treatment 27b at a temperature of not more than 1450 degrees Celsius. In this temperature range, when the temperature is excessively high, the activation of the p-type dopant such as Mg or the like may become insufficient. In addition, when the temperature is excessively high, the group III nitride semiconductor may be severely etched.

The reducing gas for the first thermal treatment 27a preferably contains at least any of hydrogen (H₂) and hydrochloric acid (HCl). The reducing gas for the second thermal treatment 27b preferably contains at least any of hydrogen (H₂) and hydrochloric acid (HCl). According to this method, as the reducing gas capable of reducing the group III nitride to be thermally-treated, gases containing e.g., hydrogen (H₂), hydrochloric acid (HCl), and the like can be used.

The nitrogen source gas for the first thermal treatment 27a can contain at least any of ammonia, a hydrazine-based substance, and an amine-based substance. The nitrogen source gas for the second thermal treatment 27b can contain at least any of ammonia, the hydrazine-based substance, and the amine-based substance. According to this method, gases containing ammonia, the hydrazine-based substance, the amine-based substance, and the like can be used as the nitrogen source gas capable of providing nitrogen, i.e., the constituent element of the target substance to be thermally treated.

One of preferable combinations of the nitrogen source gas and the reducing gas can be, for example, a combination of an ammonia gas and a hydrogen gas, or the like. In addition, in the preferable embodiment, the surface 13a of the group III nitride semiconductor layer 13 can be formed of GaN or AlGaN. The mask 19 is preferably formed of a group III nitride different from the material of the surface 13a of the group III nitride semiconductor layer 13. The mask 19 is composed of the mask film. It is possible to use, e.g., AlN and AlGaN as the material of the mask 19 and the mask film. It is possible to use the group III nitride as the mask film. In addition, the mask 19 can include, e.g., an AlN layer and an AlGaN layer. According to this method, AlN or AlGaN can be used as the mask film 15. Note that, as a matter of course, it is possible to use typical materials such as SiN and SiO₂ as the material of the mask.

After the treatment in Step S107 is performed, as shown in Part (b) of FIG. 5, in Step S111, the mask 19 is removed to expose a surface 25a of the group III nitride semiconductor 25. According to this method, when the mask 19 is formed of the group III nitride semiconductor different from the group III nitride semiconductor layer 13, the mask 19 is removed after the ion implantation, thereby exposing the surface 25a of the group III nitride semiconductor 25. In the treatment of the group III nitride semiconductor layer 13, the surface 23a exposed from the opening 19a of the mask 19 is subjected to the reducing gas and the nitrogen source gas to cause the rearrangement of atoms and the recrystallization.

When the mask 19 is made of AlN or AlGaN, it is possible to perform the removal of the mask 19 by using an alkaline aqueous solution such as, e.g., aqueous ammonia or tetramethyl ammonium hydroxide. According to this method, when the mask 19 of the group III nitride semiconductor is formed of AlN or AlGaN, wet etching is performed by using aqueous ammonia or tetramethyl ammonium hydroxide. Note that when the mask 19 is formed of SiN or SiO₂, it is possible to perform the removal by using hydrofluoric acid, buffered hydrofluoric acid, and the like.

Alternatively, before the treatment in Step S107 is performed, removing the mask 19 can expose the surface of the group III nitride semiconductor layer. According to this formation method, since the mask is formed of the group III nitride semiconductor different from the group III nitride semiconductor layer 13, removing the mask 19 after the ion implantation can expose the surface 13a of the group III nitride semiconductor layer 13. In the thermal treatment of the group III nitride semiconductor layer 13, the exposed surface 13a is subjected to the reducing gas and the nitrogen source gas to cause the rearrangement of atoms and the recrystallization.

The treatment in Step S107 can provide the semiconductor 25 with an excellent conductivity. The first thermal treatment 27a and the second thermal treatment 27b are applied to the group III nitride semiconductor 23 containing the p-type dopant to generate a region of p-type conductivity. According to this method, by the application of the first thermal treatment 27a and the second thermal treatment 27b can form the p-type conductivity region in the group III nitride semiconductor 25.

In addition, the first thermal treatment 27a and the second thermal treatment 27b are applied to the group III nitride semiconductor 23 containing the n-type dopant, thereby generating an n-type conductivity region. According to this method, by the application of the first thermal treatment 27a and the second thermal treatment 27b, it is possible to form the n-type conductivity region in the group III nitride semiconductor 25.

It is possible to apply the first thermal treatment 27a and the second thermal treatment 27b to the group III nitride semiconductor 23 containing both of the p-type dopant and the n-type dopant. In this method, the application of the first thermal treatment 27a and the second thermal treatment 27b can activate both of the p-type dopant and the n-type dopant coexisting in the group III nitride semiconductor 23.

Thus, various group III nitride semiconductors can be provided in accordance with differences in dopant species and dopant concentration. The group III nitride semiconductor 25 to which the first thermal treatment 27a and the second thermal treatment 27b are applied can include a first portion of an n-type conductivity and a second portion of a p-type conductivity. Such a dopant distribution is implemented by implanting a plurality of dopant species by using multi-step ion implantation. In this method, the application of the first thermal treatment 27a and the second thermal treatment 27b can form both the first portion of the n-type conductivity and the second portion of the p-type conductivity, both of which coexist in the group III nitride semiconductor by the activation.

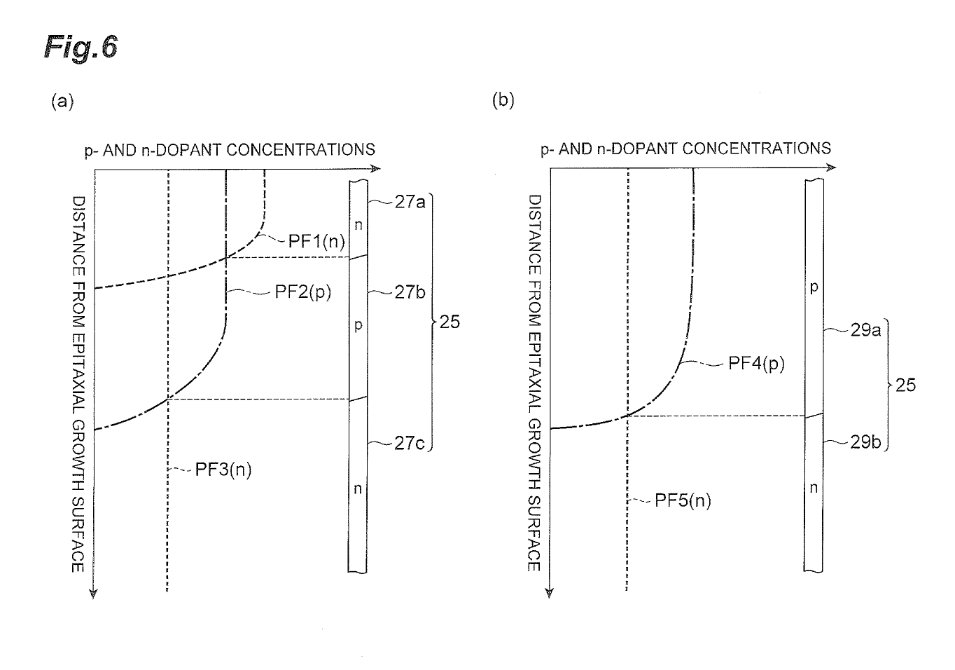

As shown in Part (a) of FIG. 6, the conductive group III nitride semiconductor 25 can include a first region 28a, a second region 28b, and a base region 28c, which are arranged in turn to from the surface of the group III nitride semiconductor in a depth direction. The conductive group III nitride semiconductor 25 has an n-type dopant profile PF1 (n), a p-type dopant profile PF2 (p), and an n-type dopant profile PF3 (n) that are defined from the surface of the group III nitride semiconductor in the depth direction.

In the present embodiment, the n-type dopant profile PF3 (n) indicates an n-type dopant concentration in an epitaxial layer 23 serving as a base. The base region 28c is defined by the n-type dopant concentration of the n-type dopant profile PF3 (n). The n-type dopant profile PF1 (n) indicates the n-type dopant concentration in the vicinity of the epitaxial growth surface. The conductivity type of the first region 28a is defined by the n-type dopant concentration of the n-type dopant profile PF1 (n). The p-type dopant profile PF2 (p) indicates the p-type dopant concentration in the middle region. The conductivity type of the second region 28b is defined by the p-type dopant concentration of the p-type dopant profile PF2 (p). In the first region 28a, the n-type dopant concentration in the n-type dopant profile PF1 (n) is higher than the p-type dopant concentration in the p-type dopant profile PF2 (p). In the second region 28b, the p-type dopant concentration in the p-type dopant profile PF2 (p) is higher than the n-type dopant concentrations in the n-type dopant profiles PF1 (n) and PF3 (n). In this method, it is possible to impart different conductivities to the first region 28a and the second region 28b disposed successively from the surface of the group III nitride semiconductor 25 in the depth direction.

The dopant profile shown in Part (a) of FIG. 6 is seen in, e.g., the longitudinal sections of a well region and a source region of a transistor. In order to form a plurality of dopant profiles, performing the ion implantation of different ion species using different acceleration energies enables the formation of different ion distances Rp.

As shown in Part (b) of FIG. 6, the conductive group III nitride semiconductor 25 can include a third region 29a and a base region 29b, which are arranged in turn from the surface of the group III nitride semiconductor in the depth direction. The conductive group III nitride semiconductor 25 has a p-type dopant profile PF4 (p) and an n-type dopant profile PF5 (n) that are defined in the depth direction from the surface of the group III nitride semiconductor. In the third region 29a, the p-type dopant concentration in the p-type dopant profile PF4 (p) is higher than the n-type dopant concentration in the n-type dopant profile PF5 (n). The n-type dopant profile PF5 (n) indicates the n-type dopant concentration in the epitaxial layer 23 serving as the base. The base region 29b is defined by the n-type dopant concentration of the n-type dopant profile PF5 (n).

The dopant profile shown in Part (b) of FIG. 6 is seen in, e.g., the longitudinal section taken along a line crossing the well region surrounding the source region of the transistor, the longitudinal section taken along a line crossing a p-type guard ring of a Schottky junction diode, and the longitudinal section taken along a line crossing the pn junction of a pn junction diode.

In the formation of the dopant profile shown in Parts (a) and (b) of FIG. 6, the p-type ion species is implanted deeply by using the mask having a large opening size, and the n-type ion species is implanted shallowly by using the mask having a small opening size, and it is thereby possible to form, e.g., the well region and the source region of the transistor. In this embodiment, the conductive group III nitride semiconductor 25 can include the third region 29a that extends from the second region 28b, and reaches the surface 25a of the conductive group III nitride semiconductor 25 so as to surround the first region 28a.

Thus, the ion implantation having different acceleration energies and different doses is performed by using a plurality of the masks having different opening sizes to provide the p-dopant profile and the n-dopant profile that are suitable for the transistor and the diode. In the description related to FIG. 6, the p- and n-dopant profiles can be translated into a first conductivity type dopant profile indicative of a first conductivity type dopant concentration and a second conductivity type dopant profile indicative of a second conductivity type dopant concentration.

In Step S112, an electrode for a semiconductor device is formed.

If necessary, in Step S115, prior to the formation of the electrode, it is possible to observe the surface of the group III nitride semiconductor after the treatment in which the reducing gas and the nitrogen source gas is used. In the observation of the semiconductor surface, an apparatus, such as, an electron microscope, an optical microscope and, more preferably a Nomarski microscope (differential interference microscope) may be used. In Step S116, when a desired morphology appears on the surface of the group III nitride semiconductor in the observation, it is determined that the subsequent treatment in the method of fabricating the semiconductor device (e.g., Step S112 and the like) is applied. According to this method, the decision can be made on whether or not the desired morphology appears on the surface of the group III nitride semiconductor after the thermal treatment, and hence information can be obtained on the presence or absence of the excellent rearrangement of atoms and the excellent recrystallization.

Subsequently, after the determination in Step S116, the formation of the electrode can be performed in Step S112. In this method, since determination is made on whether or not the morphology appears on the surface of the group III nitride semiconductor after the thermal treatment, the electrode can be formed on the conductive group III nitride semiconductor obtained as the result of the excellent rearrangement of atoms and the excellent recrystallization.

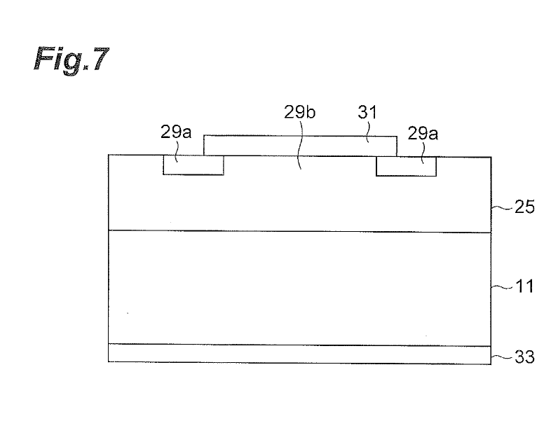

One of examples of semiconductor devices fabricated by the method of the present embodiment can include the Schottky diode. As shown in FIG. 7, the third region 29a of the conductive group III nitride semiconductor 25 includes the p-type guard ring portion of the Schottky diode. In this method, the p-type region for the guard ring can be formed in the semiconductor device.

In Step S112, the electrode for the semiconductor device is formed. As shown in FIG. 7, in Step S113, a Schottky electrode 31 has been formed. The Schottky electrode 31 is formed so as to be in contact with the third region 29a and the base region 29b of the conductive group III nitride semiconductor 25. In this method, the Schottky electrode 31 comes in contact with the semiconductor region of the excellent p-type conductivity (e.g., the third region 29a shown in (b) of FIG. 6), which can improve the breakdown voltage related to the Schottky electrode 31. In addition, in Step S112, another electrode (e.g., a back surface electrode) 33 can be formed on the conductive back surface 11b of the substrate 11. The semiconductor device can have a vertical structure.

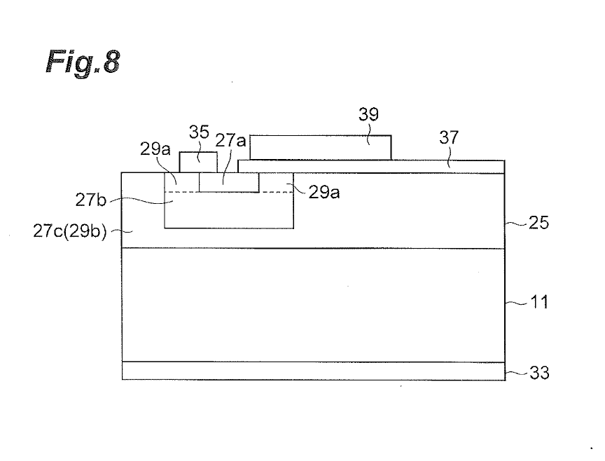

One examples of semiconductor devices fabricated by the method of the present embodiment can include the vertical transistor. As shown in FIG. 8, the second region 28b and the third region 29a of the conductive group III nitride semiconductor 25 include the well region, and the first region 28a includes the source region. The base regions 28c and 29b provide a drift region and a drain region for a current path to the substrate 11.

In Step S112, as shown in FIG. 8, the electrode for the semiconductor device is foamed. In Step S114, an ohmic electrode 35 can be formed so as to be in contact with, e.g., the well region and the source region. The ohmic electrode 35 is formed so as to be in contact with the first region 28a and the third region 29a of the conductive group III nitride semiconductor 25. In this method, since the ohmic electrode 35 is in contact with the semiconductor regions having the excellent p-type conductivity and/or the excellent n-type conductivity (the first region 28a and the third region 29a), the electrode can supply a stable potential, whereby the operation of the semiconductor device stabilized.

In addition, in the formation of the vertical transistor, a gate film 37 is formed on the well region (the region 29a), and a gate electrode 39 is formed on the gate film 37. An inversion layer is created on the surface of the well region depending upon the potential of the gate electrode 39 to control the electrical conduction between the source region and the drift region.

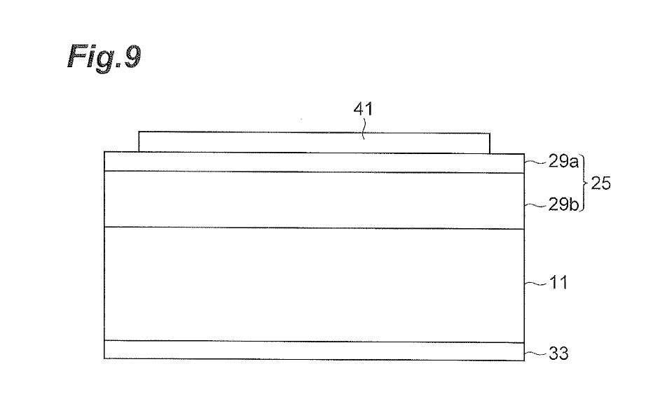

One of examples of semiconductor devices fabricated by the method of the present embodiment can include the junction diode. As shown in FIG. 9, the third region 29a of the conductive group III nitride semiconductor includes the p-type region of the junction diode. In this method, the p-type region can be formed for an anode of the semiconductor device.

In Step S112, as shown in FIG. 9, the electrode for the semiconductor device is formed. In Step S114, an ohmic electrode 41 can be formed so as to be in contact with, e.g., the anode region of the junction diode. The ohmic electrode 41 is formed so as to be in contact with the third region 29a of the conductive group III nitride semiconductor 25. In this method, since the ohmic electrode 41 is in contact with the semiconductor region having the excellent p-type conductivity, the electrode can provide the stable potential and can stabilize the operation of the semiconductor device. The third region 29a can include the anode region of the junction diode, and the base region 29b can include a cathode region of the junction diode. In the present embodiment, the third region 29a and the base region 29b constitute a pn junction. In this method, the semiconductor device can be the pn junction diode including the pn junction. If necessary, the junction diode can be fabricated and in the junction diode, the position of the p-type region and the position of the n-type region are switched.

In addition, in the present embodiment, the junction diode can be also fabricated, and the junction diode includes a pin junction, instead of the pn junction, by changing the dopant concentration and the dopant profile of the conductive group III nitride semiconductor 25. This junction diode includes an i-type region, which is interposed between the anode region of the first region and the cathode region of the second region.

Subsequently, a description will be given of Examples according to the present embodiment.

### Example 1

By growing an undoped GaN epitaxial layer having a thickness of 2 μm on a sapphire substrate, several epitaxial growth substrates A_{—}1, A_{—}2, A_{—}3, A_{—}4, A_{—}51, A_{—}52, A_{—}53, and A_{—}54 are prepared. Ion implantation is performed on these epitaxial growth substrates under the following conditions.

Ion species: Mg ion

Acceleration energy: multi-step implantation is performed such that the Mg concentration of 5×10¹⁹ cm⁻³ is achieved in a portion from 0 μm to 0.3 μm in depth

Total dose: 1.5×10¹⁵ cm⁻²

In each of the epitaxial growth substrates A_{—}51 to A_{—}54, prior to annealing, a surface protection film made of AlN having a thickness of 500 nm is grown by a metal organic vapor phase epitaxy (MOVPE) method at a growth temperature of 500 degrees Celsius.

The thermal treatment for activation is performed under the following conditions on the epitaxial growth substrates A_{—}1, A_{—}2, A_{—}3, A_{—}4, A_{—}51, A_{—}52, A_{—}53, and A_{—}54.

(1) Epitaxial growth substrate A_{—}1: in an N₂ atmosphere at the temperature of 1050 degrees Celsius for 1 minute.

(2) Epitaxial growth substrate A_{—}2: in an NH₃ atmosphere at the temperature of 1050 degrees Celsius for 1 minute.

(3) Epitaxial growth substrate A_{—}3: at the temperature of 1050 degrees Celsius, a sequence in which an NH₃+H₂ atmosphere and a H₂ atmosphere are supplied alternately is used. The sequence can include one or more unit sequences. Each unit sequence includes the first thermal treatment and the second thermal treatment. In the present embodiment, the time period of the unit sequence is, e.g., 1.5 seconds. The time period of supply of NH₃ is, e.g., 0.5 seconds, and the time period of supply of NH₃+H₂ is, e.g., 1.0 second.

During the time period of the (NH₃+H₂) atmosphere, the flow rate of H₂ is 10 slm, and the flow rate of NH₃ is also 10 slm. During the time period of the H₂ atmosphere, the flow rate of H₂ is 20 slm.

(4) Epitaxial growth substrate A_{—}4: in the H₂ atmosphere at the temperature of 1050 degrees Celsius for 1 minute.

(5-1) Epitaxial growth substrate A_{—}51: annealing is performed at the temperature of 1050 degrees Celsius for 1 minute in the N₂ atmosphere.

(5-2) Epitaxial growth substrate A_{—}52: annealing is performed at the temperature of 1200 degrees Celsius for 1 minute in the N₂ atmosphere.

(5-3) Epitaxial growth substrate A_{—}53: annealing is performed at the temperature of 1350 degrees Celsius for 1 minute in the N₂ atmosphere.

(5-4) Epitaxial growth substrate A_{—}54: annealing is performed at the temperature of 1450 degrees Celsius for 1 minute in the N₂ atmosphere.

After the thermal treatment for activation, an AlN film of each of the epitaxial growth substrates A_{—}51 to A_{—}54 is removed by wet etching using a TMAH solution (at a room temperature for 15 minutes). Thereafter, the surface of each of the epitaxial growth substrates A_{—}1, A_{—}2, A_{—}3, A_{—}4, A_{—}51, A_{—}52, A_{—}53, and A_{—}54 is observed with the optical microscope. After the observation, the ohmic electrode made of Ni is formed on the surface of each of the epitaxial growth substrates A_{—}1, A_{—}2, A_{—}3, A_{—}4, A_{—}51, A_{—}52, A_{—}53, and A_{—}54, and semiconductor devices A_{—}1, A_{—}2, A_{—}3, A_{—}4, A_{—}51, A_{—}52, A_{—}53, and A_{—}54 are formed and an alloying treatment is also performed. Thereafter, Hall measurement of the semiconductor devices A_{—}1, A_{—}2, A_{—}3, A_{—}4, A_{—}51, A_{—}52, A_{—}53, and A_{—}54 is performed. By the Hall measurement, the carrier polarity and carrier concentration are measured.

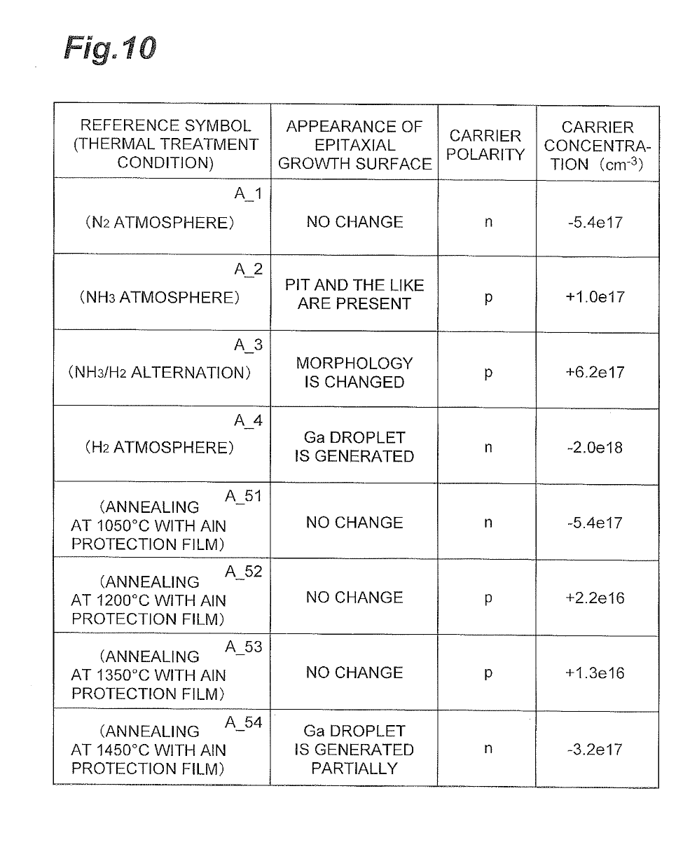

FIG. 10 is a view showing the list according to Example 1. A description will be given of the appearance of the surface of the semiconductor device. In the drawing, in the column of the carrier polarity, a symbol “n” indicates that an n-type conductivity has been formed, while a symbol “p” indicates that a p-type conductivity has been formed. With regard to symbols in the numerical value of the carrier concentration, the symbol “−” denotes an electron concentration, while the symbol “+” denote a hole concentration. For example, the notation “−5.4e17” means the electron concentration of 5.4×10¹⁷ cm⁻³.

With regard to the semiconductor device A_{—}1, no change is seen in the epitaxial growth surface after the activation treatment, and the epitaxial growth surface has excellent flatness. It is considered that no change occurs in the vicinity of the surface.

With regard to the semiconductor device A_{—}2, after the activation treatment has been performed, pits or the like are formed in the epitaxial growth surface. A treatment (reaction) by NH₃ occurs preferentially in portions, such as dislocations or local depressions, by annealing using NH₃, and hence it is considered that atoms in the portions significantly migrate to create the pits or the like.

With regard to the semiconductor device A_{—}3, after the activation treatment is performed, a clear change of a surface morphology is seen. Specifically, the generation of macro-steps or hillocks is observed. The reason for the change of the surface morphology can be as follows. A state in which a nitrogen atom is dissociated by exposure of the H₂ atmosphere in a short-time is generated. As a result, a state where atoms (especially Ga) in the epitaxial growth surface can easily move is generated, and the migration is significantly facilitated in the GaN epitaxial growth surface subjected to the ion implantation. As a result, the rearrangement of atoms in the vicinity of the surface is caused. It is considered that the recrystallization is facilitated by the supply of NH₃ of the nitrogen source to the epitaxial growth surface after the exposure to the H₂ atmosphere.

With regard to the semiconductor device A_{—}4, a Ga droplet or the like is created, which clearly means the generation of the complete decomposition of GaN by H₂.

With regard to each of the semiconductor devices A_{—}51, A_{—}52, and A_{—}53, no change is observed after the activation treatment, and the epitaxial growth surface has the excellent flatness. The epitaxial growth surface is protected by the AlN protection film (having a thickness of, e.g., 10 nm to 2000 nm) formed at low temperatures (e.g., 300 degrees Celsius to 900 degrees Celsius), and no change is thereby generated in the surface. On the other hand, with regard to the semiconductor device A_{—}54, although the AlN protection film is formed on the epitaxial growth surface and annealing is performed, Ga droplets are observed on a part of the surface by the activation treatment. It is considered that the reason for the generation is that the decomposition of GaN is caused in a part of the epitaxial layer by annealing carried out at a thermal treatment temperature of 1450 degrees Celsius.

The results of Example 1 described above has revealed p-type characteristics of the obtained GaN. With regard to the method of activating the epitaxial film subjected to the ion implantation, as compared with the method in which annealing is used in an ammonia atmosphere and the method in which an AlN cap film is used, the method related to the epitaxial growth substrate A_{—}3 is excellent. In addition, as compared with the method in which annealing is performed at high temperatures after the AlN protection film is formed, the method related to the epitaxial growth substrate A_{—}3 can provide excellent p-type characteristics at relatively low temperatures, and does not necessarily require high temperatures, so that the implementation of the method related to the epitaxial growth substrate A_{—}3 is easy.

### Example 2

An example which uses a changed implantation condition of the Mg ion will be described, and the dose of the Mg ion is reduced. According to the knowledge of the inventers, it may be difficult to obtain the p-type in this condition. On the other hand, this condition is a useful and important condition in actual electronic devices.

By growing the undoped GaN epitaxial layer having a thickness of 2 μm on the sapphire substrate, several epitaxial growth substrates B_{—}1, B_{—}2, B_{—}3, B_{—}4, B_{—}51, B_{—}52, B_{—}53, and B_{—}54 are prepared. Ion implantation is performed on these epitaxial growth substrates under the following conditions.

Ion species: Mg ion

Acceleration energy: multi-step implantation is performed such that the Mg concentration of 2×10¹⁸ cm⁻³ can be achieved in a portion from 0 μm to 0.5 μm in depth

Total dose: 1.0×10¹⁴ cm⁻²

In each of the epitaxial growth substrates B_{—}51 to B_{—}54, prior to annealing, as the surface protection film made of AlN, the AlN film having the thickness of 500 nm is grown by the metal organic vapor phase epitaxy (MOVPE) method at the growth temperature of 500 degrees Celsius.

The thermal treatment for activation is performed under the following conditions on the epitaxial growth substrates B_{—}1, B_{—}2, B_{—}3, B_{—}4, B_{—}51, B_{—}52, B_{—}53, and B_{—}54.

(1) Epitaxial growth substrate B_{—}1: in the N₂ atmosphere at the temperature of 1050 degrees Celsius for 1 minute.

(2) Epitaxial growth substrate B_{—}2: in the NH₃ atmosphere at the temperature of 1050 degrees Celsius for 1 minute.

(3) Epitaxial growth substrate B_{—}3: at the temperature of 1050 degrees Celsius, the sequence in which the NH₃+H₂ atmosphere and the H₂ atmosphere are supplied alternately is used.

During the time period of the (NH₃+H₂) atmosphere, in the first half treatment, during the time period of the H₂ atmosphere, the flow rate of H₂ is 20 slm. In the second half treatment, the flow rate of H₂ is 10 slm, and the flow rate of NH₃ is 10 slm.

(4) Epitaxial growth substrate B_{—}4: in the H₂ atmosphere at the temperature of 1050 degrees Celsius for 1 minute.

(5-1) Epitaxial growth substrate B_{—}51: annealing is performed at the temperature of 1050 degrees Celsius for 1 minute in the N₂ atmosphere.

(5-2) Epitaxial growth substrate B_{—}52: annealing is performed at the temperature of 1200 degrees Celsius for 1 minute in the N₂ atmosphere.

(5-3) Epitaxial growth substrate B_{—}53: annealing is performed at the temperature of 1350 degrees Celsius for 1 minute in the N₂ atmosphere.

(5-4) Epitaxial growth substrate B_{—}54: annealing is performed at the temperature of 1450 degrees Celsius for 1 minute in the N₂ atmosphere.

After the thermal treatment for activation, the AlN film of each of the epitaxial growth substrates B_{—}51 to B_{—}54 is removed by wet etching using the TMAH solution (at the room temperature for 15 minutes). Thereafter, the surface of each of the epitaxial growth substrates B_{—}1 to B_{—}54 is observed with the optical microscope. After the observation, the ohmic electrode made of Ni is formed on the surface of each of the epitaxial growth substrates B_{—}1 to B_{—}54, and semiconductor devices B_{—}1, B_{—}2, B_{—}3, B_{—}4, B_{—}51, B_{—}52, B_{—}53, and B_{—}54 are formed and the alloying treatment thereof is also performed. Thereafter, the Hall measurement of the semiconductor devices B_{—}1 to B_{—}54 is performed. By the Hall measurement, the carrier polarity and carrier concentration are estimated.

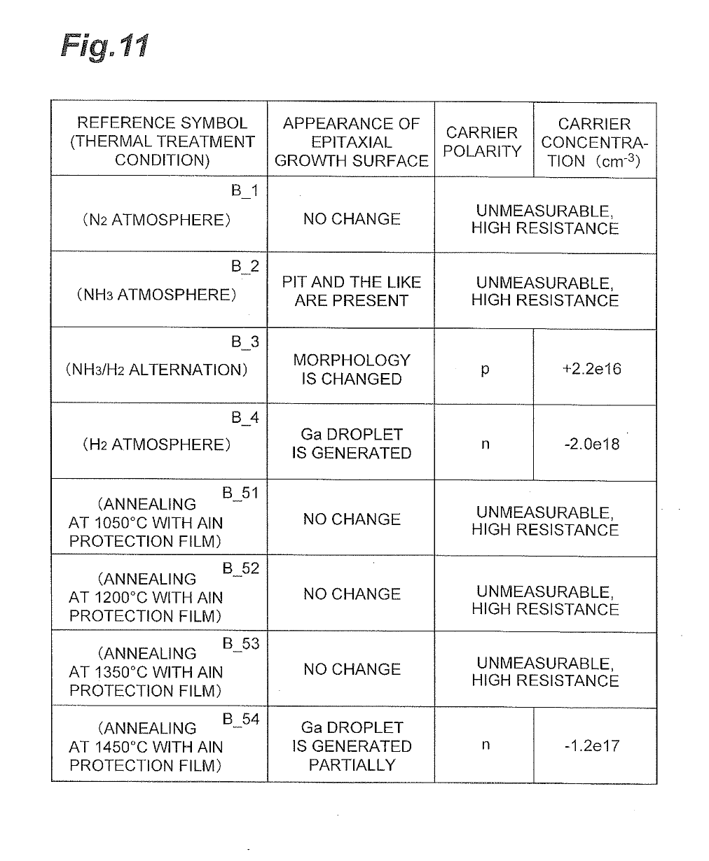

FIG. 11 is a view showing the list according to Example 2. In the drawing, in the column of the carrier polarity, the symbol “n” indicates that a conductivity formed is n-type, while the symbol “p” indicates that a conductivity formed is p-type. With regard to the symbol in the numerical value of the carrier concentration, the symbol “−” denotes the electron concentration, while the symbol “+” denotes the hole concentration. The surface morphology according to Example 2 exhibits the tendency similar to that of Example 1. The condition of the thermal treatment is useful for the activation of the implantation ion species in high dose to medium dose of the ion implantation.

With regard to the semiconductor device B_{—}3, after the activation treatment is performed, a clear change of the surface morphology is observed. Specifically, the observation shows that micro-steps or hillocks are generated. The reason for the change of the surface morphology is as follows. A state where the nitrogen atom is dissociated by the exposure of the H₂ atmosphere in a short-time is generated. As a result, the state where atoms (especially Ga) in the epitaxial growth surface can easily migrate is generated, and the migration is significantly increased in the vicinity of the GaN epitaxial growth surface subjected to the ion implantation. As a result, the rearrangement of atoms in the vicinity of the surface is caused. It is considered that the recrystallization is facilitated by the supply of NH₃ to the epitaxial growth surface after the exposure the H₂ atmosphere.

In Example 2, a p-type gallium nitride having a low Mg concentration can be obtained, and this p-type gallium nitride is used in the actual application to the electronic device or the like.

### Example 3

An example will be described and in this example, a change is made in the condition of the activation treatment (the temperature when alternate annealing is performed). As the implantation condition of the Mg ion, the low dose in Example 2 is also used in this example. The dose in the present condition is lower than that of the condition in Example 1, and hence it may be difficult to obtain the p-type.

By growing the undoped GaN epitaxial layer having the thickness of 2 μm on the sapphire substrate, several epitaxial growth substrates C_{—}1, C_{—}2, C_{—}3, C_{—}4, C_{—}5, C_{—}6, C_{—}7, C_{—}8, and C_{—}9 are prepared. Ion implantation is performed on these epitaxial growth substrates under the following conditions.

Ion species: Mg ion

Acceleration energy: multi-step implantation is performed such that the Mg concentration of 2×10¹⁸ cm⁻³ can be achieved in a portion from 0 μm to 0.5 μm in depth

Total dose: 1.0×10¹⁴ cm⁻²

The thermal treatment for activation is performed under the following conditions on the epitaxial growth substrates C_{—}1 to C_{—}9.

With regard to the treatment gas in the thermal treatment, the sequence in which the NH₃+H₂ atmosphere (0.5 seconds) and the H₂ atmosphere (1.0 second) are alternately supplied is used.

During the time period of the (NH₃+H₂) atmosphere, the flow rate of H₂ is 10 slm, and the flow rate of NH₃ is also 10 slm. During the time period of the H₂ atmosphere, the flow rate of H₂ is 20 slm.

(1) Epitaxial growth substrate: C_{—}1: annealing is performed at the temperature of 700 degrees Celsius.

(2) Epitaxial growth substrate: C_{—}2: annealing is performed at the temperature of 800 degrees Celsius.

(3) Epitaxial growth substrate: C_{—}3: annealing is performed at the temperature of 900 degrees Celsius.

(4) Epitaxial growth substrate: C_{—}4: annealing is performed at the temperature of 1000 degrees Celsius.

(5) Epitaxial growth substrate: C_{—}5: annealing is performed at the temperature of 1050 degrees Celsius.

(6) Epitaxial growth substrate: C_{—}6: annealing is performed at the temperature of 1100 degrees Celsius.

(7) Epitaxial growth substrate: C_{—}7: annealing is performed at the temperature of 1200 degrees Celsius.

(8) Epitaxial growth substrate: C_{—}8: annealing is performed at the temperature of 1250 degrees Celsius.

(9) Epitaxial growth substrate: C_{—}9: annealing is performed at the temperature of 1300 degrees Celsius.

Thereafter, the surface of each of the epitaxial growth substrates C_{—}1 to C_{—}9 is observed with the optical microscope. After the observation, the ohmic electrode made of Ni is formed on the surface of each of the epitaxial growth substrates C_{—}1 to C_{—}9, and the alloying treatment is also performed to form semiconductor devices C_{—}1 to C_{—}9. Thereafter, the Hall measurement of the semiconductor devices C_{—}1 to C_{—}9 is performed. By the Hall measurement, the carrier polarity and carrier concentration are obtained.

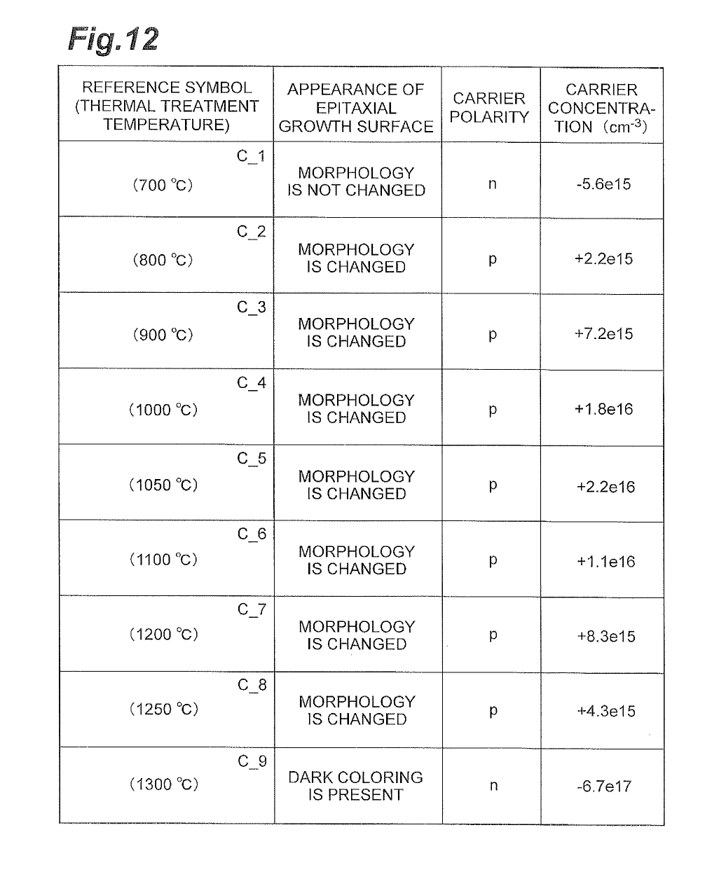

FIG. 12 is a view showing the list according to Example 3. In the drawing, in the column of the carrier polarity, the symbol “n” indicates that a conductivity formed is n-type, while the symbol “p” indicates that a conductivity formed is p-type. With regard to the symbol in the numerical value of the carrier concentration, the symbol “−” denotes the electron concentration, while the symbol “+” denote the hole concentration. In addition, the thermal treatment can be carried out on the group III nitride semiconductor subjected to the ion implantation at a temperature in a range of not less than 800 degrees Celsius and not more than 1450 degrees Celsius by using the reducing gas that provide a reducing atmosphere therein. When the alternate annealing is performed, the activation of the p-type dopant can be can be performed in the range of 800 degrees Celsius to 1250 degrees Celsius. Note that, before the alternate annealing is performed, pre-annealing can be applied thereto, e.g., at a temperature of not more than 1400 degrees Celsius in the nitrogen atmosphere. This above-described treatment can recover the damage caused by the ion implantation and the alternate annealing can improve the activation rate of the p-type dopant.

### Example 4

An example will be described, and in this example, the implantation of a carbon (C) ion instead of the magnesium (Mg) ion is performed. By growing the undoped GaN epitaxial layer having the thickness of 2 μm on the sapphire substrate, several epitaxial growth substrates D_{—}1, D_{—}2, D_{—}3, D_{—}4, D_{—}51, D_{—}52, D_{—}53, and D_{—}54 are prepared. Ion implantation is performed on these epitaxial growth substrates under the following conditions.

Ion species: C ion

Acceleration energy: multi-step implantation is performed such that the Mg concentration of 5×10¹⁹ cm⁻³ is achieved in a portion from 0 μm to 0.3 μm in depth

Total dose: 1.5×10¹⁵ cm⁻²

In each of the epitaxial growth substrates D_{—}51 to D_{—}54, prior to annealing, the AlN film having the thickness of 500 nm, serving as the surface protection film made of AlN, is grown by the metal organic vapor phase epitaxy (MOVPE) method at the growth temperature of 500 degrees Celsius.

The thermal treatment for activation is performed under the following conditions on the epitaxial growth substrates D_{—}1, D_{—}2, D_{—}3, D_{—}4, D_{—}51, D_{—}52, D_{—}53, and D_{—}54.

(1) Epitaxial growth substrate D_{—}1: in the N₂ atmosphere at the temperature of 1050 degrees Celsius for 1 minute.

(2) Epitaxial growth substrate D_{—}2: in the NH₃ atmosphere at the temperature of 1050 degrees Celsius for 1 minute.

(3) Epitaxial growth substrate D_{—}3: at the temperature of 1050 degrees Celsius in the sequence in which the NH₃+N₂ atmosphere (0.5 seconds) and the H₂ atmosphere (1.0 second) are supplied alternately is used. During the time period of the (NH₃+H₂) atmosphere, the flow rate of H₂ is 10 slm, and the flow rate of NH₃ is also 10 slm.

During the time period of the H₂ atmosphere, the flow rate of H₂ is 20 slm.

(4) Epitaxial growth substrate D_{—}4: in the H₂ atmosphere at the temperature of 1050 degrees Celsius for 1 minute.

(5-1) Epitaxial growth substrate D_{—}51: annealing is performed at the temperature of 1050 degrees Celsius for 1 minute in the N₂ atmosphere.

(5-2) Epitaxial growth substrate D_{—}52: annealing is performed at the temperature of 1200 degrees Celsius for 1 minute in the N₂ atmosphere.

(5-3) Epitaxial growth substrate D_{—}53: annealing is performed at the temperature of 1350 degrees Celsius for 1 minute in the N₂ atmosphere.

(5-4) Epitaxial growth substrate D_{—}54: annealing is performed at the temperature of 1450 degrees Celsius for 1 minute in the N₂ atmosphere.

After the thermal treatment for activation, the MN film of each of the epitaxial growth substrates D_{—}51 to D_{—}54 is removed by wet etching using the TMAH solution (at the room temperature for 15 minutes). Thereafter, the surface of each of the epitaxial growth substrates D_{—}1 to D_{—}54 is observed with the optical microscope. After the observation, the ohmic electrode made of Ni is formed on the surface of each of the epitaxial growth substrates D_{—}1 to D_{—}54, and the alloying treatment is also performed to form semiconductor devices D_{—}1 to D_{—}54. Thereafter, the Hall measurement of the semiconductor devices D_{—}1 to D_{—}54 is performed. By the Hall measurement, the carrier polarity and carrier concentration can be obtained.

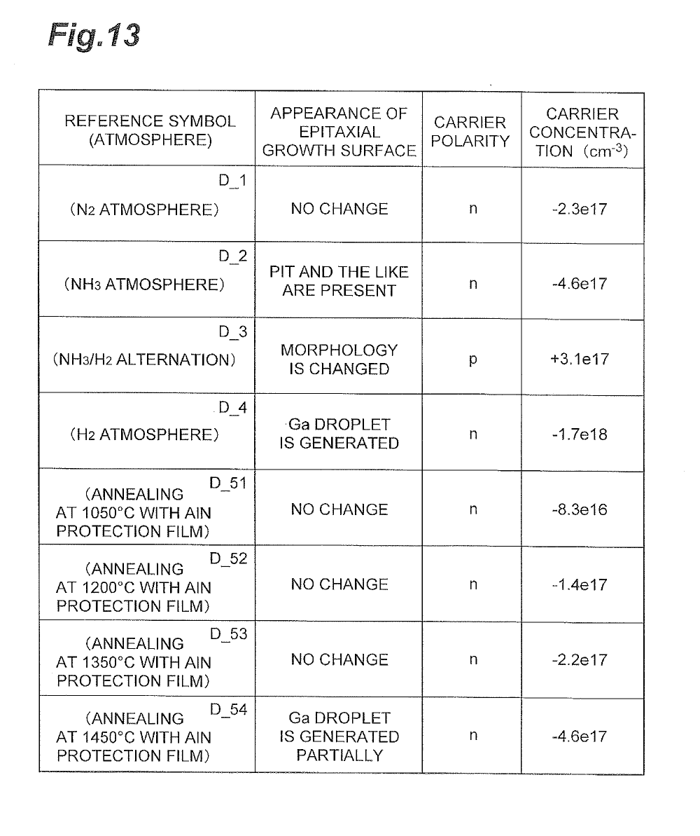

FIG. 13 is a view showing the list according to Example 4. A description will be given of the appearance of the surface of the semiconductor device. In the drawing, in the column of the carrier polarity, the symbol “n” indicates that a conductivity formed is n-type, while the symbol “p” indicates that a conductivity formed is p-type. With regard to the symbol in the numerical value of the carrier concentration, the symbol “−” denotes the electron concentration, while the symbol “+” denote the hole concentration. When carbon (C) is used as the dopant, by performing alternate annealing in which NH₃ and H₂ are supplied alternately, carbon (C) is activated as the p-type dopant, thereby providing p-type GaN.

With regard to the semiconductor device C_{—}3, after the activation treatment is performed, a significant change is made in the surface morphology, and specifically, the generation of the micro-step or the hillock is observed. The reason for the change of the surface morphology may be as follows. The state where the nitrogen atom is dissociated by exposure of the H₂ atmosphere in a short time is generated. As a result, the state where atoms (especially Ga) in the epitaxial growth surface can easily move is generated, and the migration is significantly increased in the vicinity of the GaN epitaxial growth surface subjected to the ion implantation. As a result, the rearrangement of atoms in the vicinity of the surface is caused. It is considered that the recrystallization was facilitated by the supply of NH₃ to the epitaxial growth surface after the exposure to the H₂ atmosphere.

Even with other dopants such as, e.g., zinc (Zn), calcium (Ca), yttrium (Y), and beryllium (Be), the ion species is activated as the p-type dopant, and p-type GaN can be obtained.

### Example 5

An example will be described, and in this example, the ion implantation of Si is carried out. The ion implantation of the n-type dopant is applied to form a contact layer of the electronic device (formation of a selected n-layer and an n⁺-layer). This is practically extremely important.

By growing the undoped GaN epitaxial layer having the thickness of 2 μm on the sapphire substrate, several epitaxial growth substrates E_{—}1, E_{—}2, E_{—}3, E_{—}4, E_{—}51, E_{—}52, E_{—}53, and E_{—}54 are prepared. Ion implantation is performed on these epitaxial growth substrates under the following conditions.

Ion species: Si ion

Acceleration energy: multi-step implantation is performed such that the Si concentration of 5×10¹⁸ cm⁻³ is achieved in a portion from 0 μm to 0.3 μm in depth

Total dose: 1.7×10¹⁴ cm⁻²

In each of the epitaxial growth substrates E_{—}51 to E_{—}54, prior to annealing, as the surface protection film made of AlN, the AlN film having the thickness of 500 nm is grown by the metal organic vapor phase epitaxy (MOVPE) method at the growth temperature of 500 degrees Celsius.

The thermal treatment for activation is performed under the following conditions on the epitaxial growth substrates E_{—}1, E_{—}2, E_{—}3, E_{—}4, E_{—}51, E_{—}52, E_{—}53, and E_{—}54.

(1) Epitaxial growth substrate E_{—}1: in the N₂ atmosphere at the temperature of 1050 degrees Celsius for 1 minute.

(2) Epitaxial growth substrate E_{—}2: in the NH₃ atmosphere at the temperature of 1050 degrees Celsius for 1 minute.

(3) Epitaxial growth substrate E_{—}3: at the temperature of 1050 degrees Celsius in the sequence in which the (NH₃+H₂) atmosphere (0.5 seconds) and the H₂ atmosphere (1.0 second) are supplied alternately is used.

During the time period of the (NH₃+H₂) atmosphere, the flow rate of H₂ is 10 slm, and the flow rate of NH₃ is also 10 slm. During the time period of the H₂ atmosphere, the flow rate of H₂ is 20 slm.

(4) Epitaxial growth substrate E_{—}4: in the H₂ atmosphere at the temperature of 1050 degrees Celsius for 1 minute.

(5-1) Epitaxial growth substrate E_{—}51: annealing is performed at the temperature of 1050 degrees Celsius for 1 minute in the N₂ atmosphere.

(5-2) Epitaxial growth substrate E_{—}52: annealing is performed at the temperature of 1200 degrees Celsius for 1 minute in the N₂ atmosphere.

(5-3) Epitaxial growth substrate E_{—}53: annealing is performed at the temperature of 1350 degrees Celsius for 1 minute in the N₂ atmosphere.

(5-4) Epitaxial growth substrate E_{—}54: annealing is performed at the temperature of 1450 degrees Celsius for 1 minute in the N₂ atmosphere.

After the thermal treatment for activation, the MN film of each of the epitaxial growth substrates E_{—}51 to E_{—}54 is removed by wet etching using the TMH solution (wet etching treatment at the room temperature for 15 minutes).

Thereafter, the surface of each of the epitaxial growth substrates E_{—}1 to E_{—}54 is observed with the optical microscope.

After the observation, the ohmic electrode made of Ni is formed on the surface of each of the epitaxial growth substrates E_{—}1 to E_{—}54, and the alloying treatment is also performed to form semiconductor devices E_{—}1 to E_{—}54. Thereafter, the Hall measurement of the semiconductor devices E_{—}1 to E_{—}54 is performed. By the Hall measurement, the carrier polarity and carrier concentration are obtained.

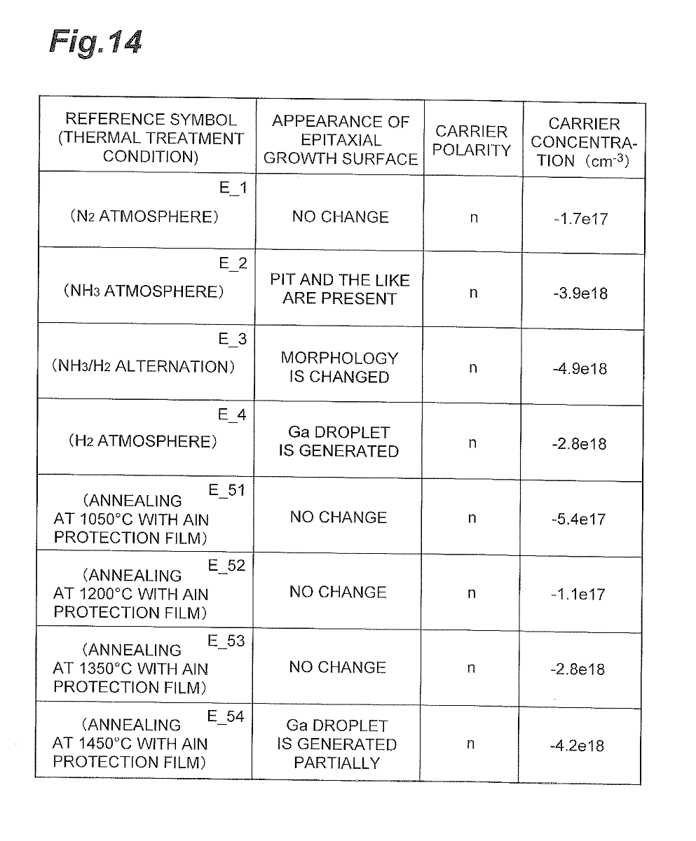

FIG. 14 is a view showing the summary of Example 4. A description will be given of the appearance of the surface of the semiconductor device. In the drawing, in the column of the carrier polarity, the symbol “n” indicates that the n conductivity is formed. With regard to the symbol in the numerical value of the carrier concentration, the symbol “−” denotes the electron concentration.

Referring to the column of the Si concentration, the condition of each of the epitaxial growth substrates E_{—}1 and E_{—}3 indicates a relatively high carrier concentration in this Example as well, and the method for the epitaxial growth substrates E_{—}1 and E_{—}3 can provide excellent activation.

### Example 6

Examples described above will be summarized. In each of above Examples, after the ion implantation of Mg, C, or Si as the ion species is performed on GaN, various thermal treatments are successively performed for the activation of GaN. As one of the treatments, the thermal treatment is performed while alternately performing the supply of the (NH₃+H₂) and the supply of the H₂. In this thermal treatment, the nitrogen source, such as ammonia, and the reducing atmosphere, such as hydrogen (etching gas), are alternately provided. In the gases alternately supplied, it is not necessary to completely separate H₂ and NH₃ from each other, and it is possible to perform the thermal treatment in which the activation target is placed alternately in a first atmosphere containing the nitrogen source gas (e.g., NH₃) and a second atmosphere containing the reducing gas (e.g., H₂) and the nitrogen source (e.g., NH₃ smaller than that in the first atmosphere). In the thermal treatment, the ratio between the first atmosphere and the second atmosphere can be periodically changed. This arrangement of the supply sequence can activate various ion species in the group III nitride semiconductor.

In addition, the atmosphere of the nitrogen source is not limited to the combination of hydrogen and ammonia, and can be made of a gas that can serve as the nitrogen source for the constituent element of the group III nitride semiconductor grown. Gas, such as a hydrazine-based gas, an amine-based gas, a nitrogen radical, plasma-converted nitrogen, and plasma-converted ammonia can serve as the nitrogen source, in addition to ammonia. Further, the reducing atmosphere (etching gas) can be formed by the gas that has a reduction action on the group III nitride semiconductor. Gas, such as, hydrogen chloride (e.g., HCl) and chlorine (e.g., Cl₂) can serve as the reducing atmosphere (etching gas), in addition to hydrogen, and there can also be used a hydrogen radical, plasma-converted hydrogen, and plasma-converted argon.

Further, Examples explained above describe experiments in which Mg, C, and Si are used as the elements of the ion implantation. However, as the n-type dopant, it is also possible to use germanium or the like. In addition, as the p-type dopant, it is also possible to use zinc, calcium, yttrium, carbon, and beryllium. When these dopants are used, the same effects as those in Examples can be obtained.

Furthermore, in each of the above examples, the GaN layer is used as the group III nitride semiconductor. The annealing method in Examples is also applied to the group III nitride semiconductor, AlGaN, InGaN, AlInGaN and the like to obtain the p-conductivity and the n-conductivity, which are obtained from the p-dopant and the n-dopant introduced by the ion implantation, respectively.

The examples of a treatment of the repetition of the nitrogen source atmosphere and the reducing atmosphere can encompass a treatment in which the ammonia atmosphere, the hydrogen atmosphere, and the ammonia atmosphere are used in this order by appropriately selecting treatment conditions such as the treatment time, the thermal treatment temperature, and the pressure of the atmosphere. The above examples can encompass the treatment of an additional repetition thereof.

### Example 7

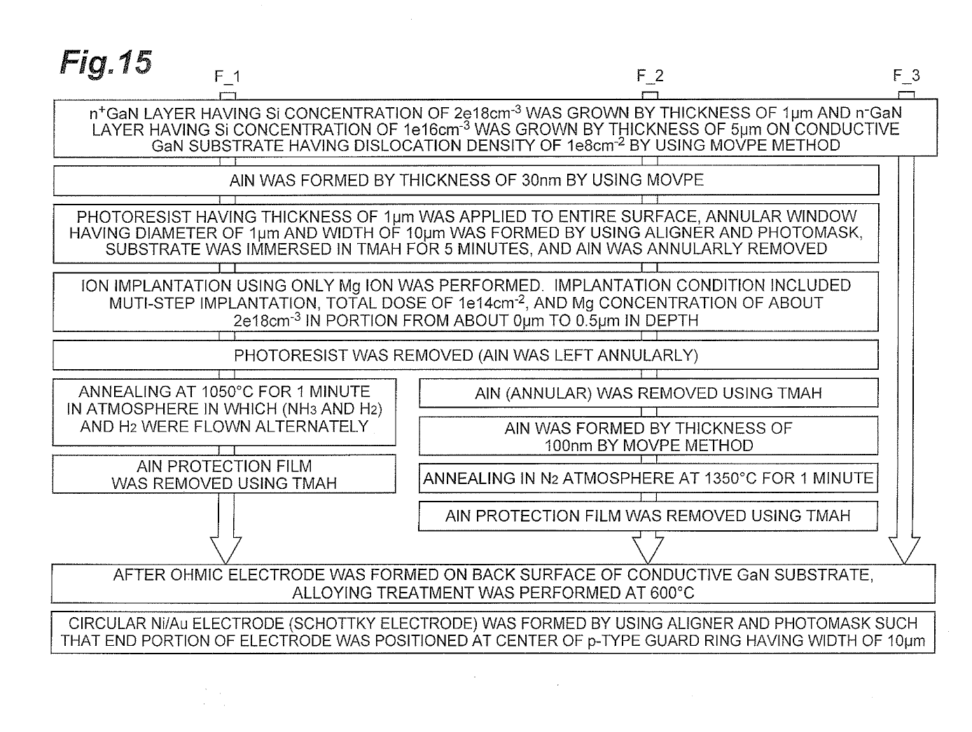

According to the process flow shown in FIG. 15, a description will be given of a Schottky barrier diode as the semiconductor device. The

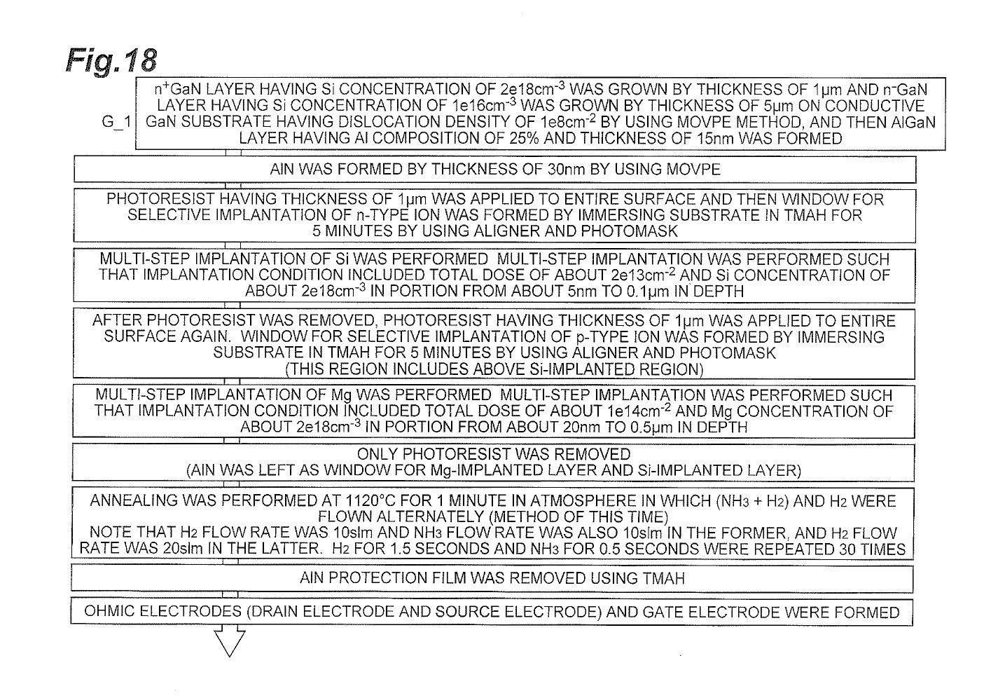

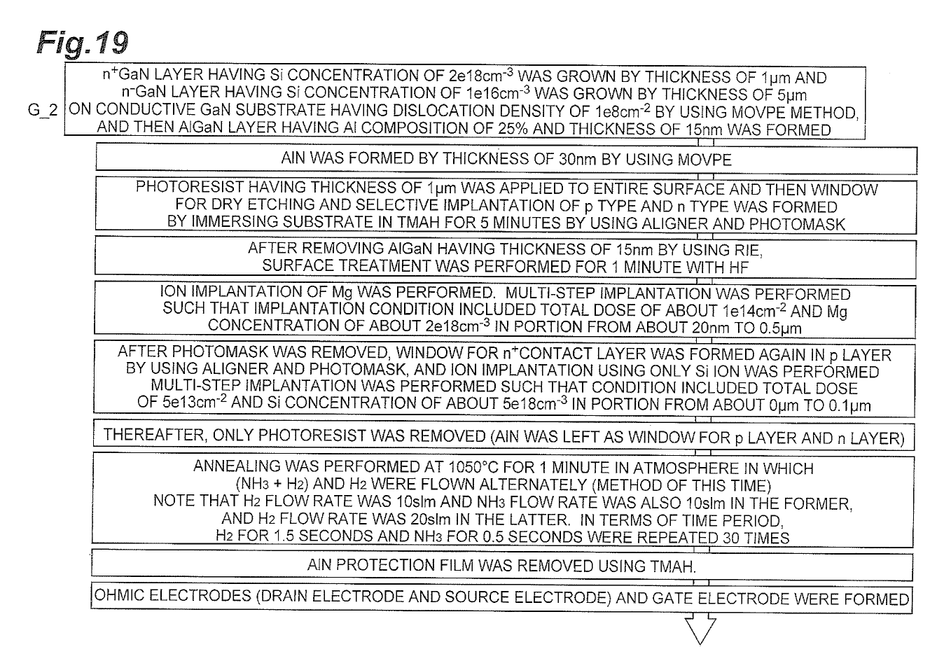

Schottky barrier diode including the p-type guard ring is fabricated. As the conductive substrate, a conductive GaN wafer having a dislocation density of 1×10⁸ cm⁻² is prepared. On the GaN substrate, an n⁺GaN layer having an Si concentration of 2×10⁸ cm⁻³ and a thickness of 1 μm, and an n⁻GaN layer having an Si concentration of 1×10¹⁶ cm⁻³ and a thickness of 5 μm are grown successively by an MOVPE method to fabricate the epitaxial grown substrate. In the notation in FIG. 15, “1 e 8 cm⁻²” denotes the surface density of “1×10⁸ cm⁻²”, and “2 e 18 cm⁻³” denotes the concentration of “2×10¹⁸ cm⁻³”. The similar notation is also used in FIGS. 18 and 19.

Experiment F_{—}1

The Schottky barrier diode having the p-type guard ring is fabricated. After the AlN film having a thickness of 30 nm is grown by a MOVPE method on the epitaxial growth substrate described above, a photoresist having a thickness of 1 μm is applied to the entire surface thereof, and then a resist mask having an annular window, which has a size of a diameter of 1 mm and a width of 10 μm, is formed by using an aligner and a photo mask. Subsequently, for the etching of the AN film, the epitaxial growth substrate is immersed in the TMAH solution for 5 minutes. An AlN mask having an annular opening is formed. By using the MN mask, ion implantation using only the Mg ion is performed on the epitaxial growth substrate. The conditions of the ion implantation are as follows: multi-step ion implantation is performed with the total dose of 1×10¹⁴ cm⁻² such that a Mg concentration of about 2×10¹⁸ cm⁻³ is achieved in a portion from the epitaxial growth surface to 0.5 μm in depth. As a result, an annular Mg-implanted region having a diameter of 1 mm and a width of 10 μm is formed in the GaN layer by use of the opening of the AlN mask. Only the resist mask is removed after the ion implantation, and the AlN mask is left.

As the annealing treatment, the following annealing is carried out: the annealing is performed at the temperature of 1050 degrees Celsius for 1 minute while alternately supplying the atmospheres of (the mixed gas of NH₃ and H₂) and H₂. In the atmosphere of the mixed gas of NH₃ and H₂, the flow rate of H₂ is 10 slm, and the flow rate of NH₃ is 10 slm. In the atmosphere of H₂, the flow rate of H₂ is 20 slm. In this sequence, a time period of one cycle is 1.5 seconds. Hydrogen is flown during the time period of 1.5 seconds, and ammonia is flown during the time period of 0.5 seconds. Thereafter, the AlN mask is removed by using TMAH, and then annealing is performed in the N₂ atmosphere at 850 degrees Celsius for 2 minutes.

Experiment F_{—}2

After the ion implantation, the AlN mask having the annular opening is removed by using the TMAH solution. After the removal, the AlN layer having a thickness of 100 nm is grown on the entire surface again by a MOVPE method. After the film formation, annealing is performed in the N₂ atmosphere at 1350 degrees Celsius for 1 minute. After the annealing, the AlN layer is removed by using the TMAH solution.

The ohmic electrode is formed on the back surface of the conductive GaN substrate of each of the epitaxial growth substrates F_{—}1 and F_{—}2 fabricated by Experiments. Thereafter, the alloying treatment is performed at 600 degrees Celsius. Thereafter, by using the aligner and the photo mask, a circular Schottky electrode (Ni/Au electrode) is formed such that the end portion of the electrode is located inside the p-type guard ring having the width of 10 μm.

Experiment F_{—}3

The Schottky barrier diode without the p-type guard ring is fabricated. After the epitaxial growth substrate is fabricated by epitaxial growth, the ohmic electrode is formed on the back surface of the conductive GaN substrate, and the alloying treatment is performed at 600 degrees Celsius. Thereafter, by using the aligner and the photo mask, the circular (diameter of 1 mm) Schottky electrode (Ni/Au electrode) is formed.

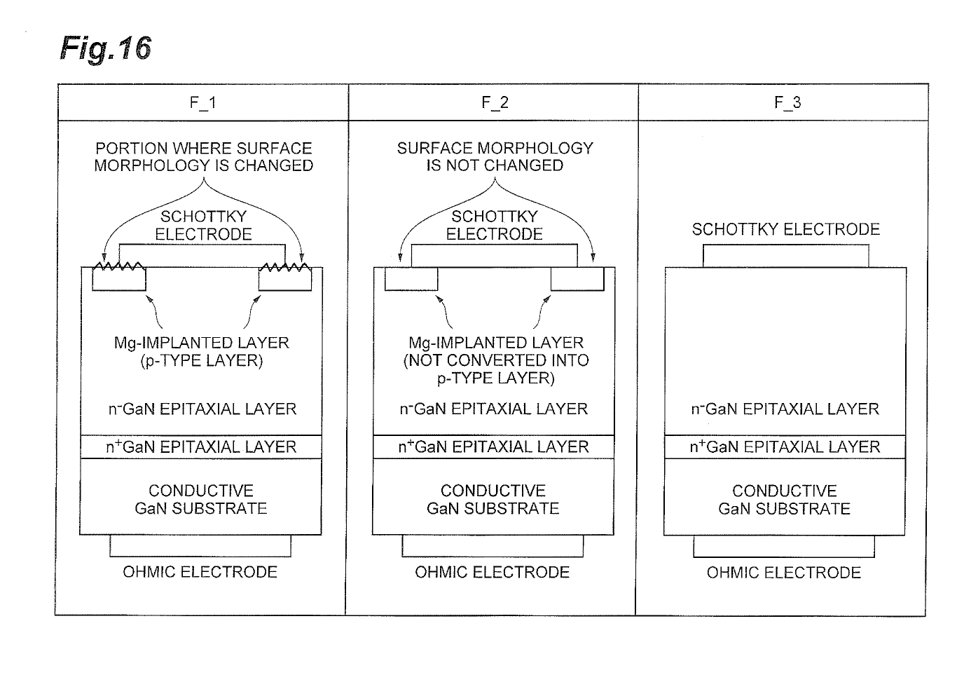

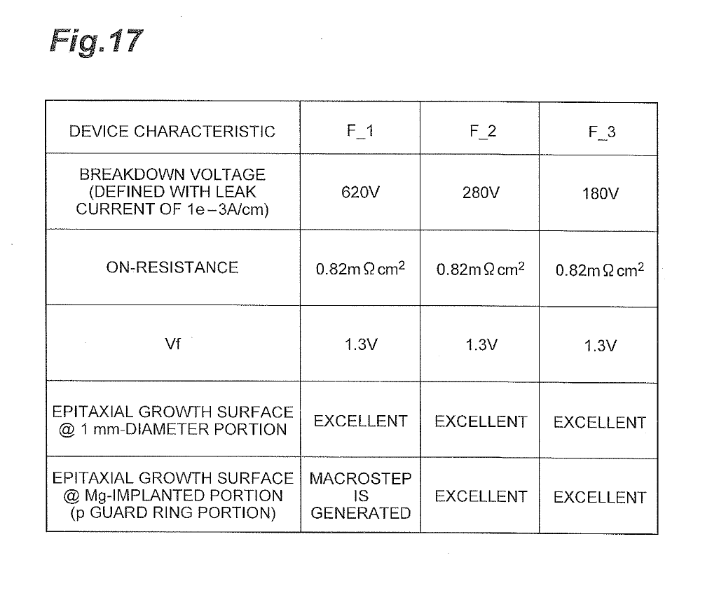

By Experiments described above, the Schottky barrier diodes having the structures shown in FIG. 16 are fabricated. With reference to FIG. 17, a description will be given of characteristics of the Schottky barrier diodes F_{—}1, F_{—}2, and F_{—}3 fabricated by three Experiments described above. The Schottky barrier diodes F_{—}1, F_{—}2, and F_{—}3 have the same forward characteristics such as an on-resistance and a forward voltage Vf. With regard to the breakdown voltage related to reverse characteristics, among the three Schottky barrier diodes, the Schottky barrier diode F_{—}1 has the highest value of the reverse breakdown voltage, which indicates that excellent p-type characteristics applicable to the guard ring can be fabricated by the ion implantation and the activation annealing.

In Experiment F_{—}1, only the surface of a p-type guard ring layer, i.e., the surface of the GaN layer having the part that is subjected to the Mg ion implantation is exposed to the atmosphere of the alternate annealing that uses NH₃ and H₂. At least a portion of the exposed surface has a morphology comprising a macro-step or the like, and the morphology in this portion exhibits the appearance different from that of the portion covered with the AlN mask. Such a macro-step does not influence electrical characteristics such as a Schottky barrier diode breakdown voltage and the like. In the present Example, although the Schottky barrier diode having the p-type guard ring is fabricated, the present embodiment can be applied to other semiconductor devices such as different diodes.

### Example 8

According to the process flows shown in FIGS. 18 and 19, a description will be given of the vertical transistor as the semiconductor device. The vertical transistor having an AlGaN channel is fabricated. A conductive GaN wafer having a dislocation density of 1×10⁸ cm⁻² is prepared. On the GaN substrate, an n⁺GaN layer having an Si concentration of 2×10¹⁸ cm⁻³ and a thickness of 1 μm, an n⁻GaN layer having an Si concentration of 1×10¹⁶ cm⁻³ and a thickness of 5 μm, and an undoped AlGaN layer (Al composition: 0.25) having a thickness of 15 nm are grown in turn by a MOVPE method to fabricate the epitaxial growth substrate.

Experiment G1 (a Fabrication Method with the AlGaN Layer Left)

The vertical transistor is fabricated. After the AlN film having a thickness of 500 nm is grown on the above epitaxial growth substrate by using a MOVPE method, the photoresist having a thickness of 1 μm is applied to the entire surface of the substrate. After the application, by using the aligner and the photo mask, the resist mask having the window for an n-type contact region is formed. Subsequently, the substrate is immersed in the TMAH solution for 5 minutes for the etching of the AlN film, to form the AlN mask having the opening for the n-type contact region. By using the AlN mask formed in this manner, the ion implantation using only the Si ion is performed on the epitaxial growth substrate. The conditions of the ion implantation are as follows: multi-step ion implantation is performed with the total dose of 5×10¹³ cm⁻² such that an Si concentration of about 5×10¹⁸ cm⁻³ is achieved in a portion from 20 nm from the epitaxial growth surface to 0.1 μm in depth. As a result, an Si-implanted region for the n-type contact region is formed. after the ion implantation, Only the resist mask is removed and the AlN mask is left.

After the removal of the resist mask, the photoresist having a thickness of 1 μm is applied to the entire surface of the substrate again. By using the aligner and the photo mask, the resist mask having the window for a p-type well is formed. Subsequently, for the etching of the AlN mask (AlN film), the substrate is immersed in the TMAH solution for 5 minutes. The AlN mask having an opening for the p-type well is formed from the AlN mask. By using the new AlN mask, the ion implantation using only the Mg ion is performed on the epitaxial growth substrate. The conditions of the ion implantation are as follows: multi-step ion implantation is performed with the total dose of 1×10¹⁴ cm⁻² such that a Mg concentration of about 2×10¹⁸ cm⁻³ is achieved in a portion from 20 nm to 0.5 μm in depth, which indicate values defined as a distance from the epitaxial growth surface. As a result, the Mg-implanted region for the p-type well region is formed. After the second ion implantation, only the resist mask is removed, and the AlN mask having the resized opening is left.

After the second ion implantation, a Mg-implanted layer and an Si-implanted layer are exposed in the opening of the AlN mask. As the annealing treatment after the ion implantation, the following conditions are used: annealing is performed at the temperature of 1120 degrees Celsius for 1 minute while supplying the atmospheres of (the mixed gas of NH₃ and H₂) and H₂. In the atmosphere of the mixed gas of NH₃ and H₂, the flow rate of H₂ is 10 slm, and the flow rate of NH3 is 10 slm. In the atmosphere of H₂, the flow rate of H₂ is 20 slm. In this sequence, hydrogen is flown during the time period of 1.5 seconds, ammonia is flown during the time period of 0.5 seconds, and the time period of one cycle is 1.5 seconds. Thereafter, the MN mask is removed by using TMAH, and then annealing is performed in the N₂ atmosphere at 8.50 degrees Celsius for 2 minutes. Thereafter, the AlN mask is removed by using the TMAH solution. The above processing makes it possible to activate Mg (p-type layer), and Si (n-type layer) implanted into the region implanted with the Mg. The ohmic electrodes (drain electrode and source electrode) and the gate electrode are formed on the annealed epitaxial growth substrate.

Experiment G2

The vertical transistor is fabricated. After the AlN film having a thickness of 30 nm is grown by using MOVPE on the above-described epitaxial growth substrate, the AlGaN layer having a thickness of 15 nm is partially removed by reactive ion etching. Thereafter, a surface treatment is performed for 1 minute using hydrofluoric acid (HF).

After the photoresist having a thickness of 1 μm is applied to the entire surface after the etching, the resist mask having the window for the n-type contact region is formed by using the aligner and the photo mask. Subsequently, for the etching of the AlN film, the substrate is immersed in the TMAH solution for 5 minutes. By using this AlN mask, the ion implantation of only Si ion is performed to the epitaxial growth substrate. The conditions of the ion implantation are as follows: multi-step ion implantation is performed with the total dose of 5×10¹³ cm⁻² such that an Si concentration of about 5×10¹⁸ cm³ is achieved in a portion from 20 nm to 0.1 μm, and these values are defined as a distance from the epitaxial growth surface in depth. As a result, the Si-implanted region for the n-type contact region is formed.

After the removal of the resist mask, the photoresist having a thickness of 1 μm is applied to the entire surface again, and then the resist mask having the window for the p-type well is formed. Subsequently, for the etching of the AlN film, the substrate is immersed in the TMAH solution for 5 minutes. The AlN mask having the opening for the p-type well is formed. By using this AlN mask, the ion implantation of only the Mg ion is performed to the epitaxial growth substrate. The conditions of the ion implantation are as follows: multi-step ion implantation is performed with the total dose of 1×10¹⁴ cm⁻² such that a Mg concentration of about 2×10¹⁸ cm⁻³ is achieved in a portion from 20 nm to 0.5 μm, and these values are defined as a distance from the epitaxial growth surface in depth. As a result, the Mg-implanted region for the p-type well region is formed. Only the resist mask is removed after the ion implantation, and the AlN mask is left.

The Mg-implanted layer and the Si-implanted layer are exposed in the opening of the AlN mask. As the annealing treatment, the following conditions are used: annealing is performed at the temperature of 1120 degrees Celsius for 1 minute while alternately supplying the atmospheres of (the mixed gas of NH₃ and H₂) and H₂. In the atmosphere of the mixed gas of NH₃ and H₂, the flow rate of H₂ is 10 slm, and the flow rate of NH₃ is 10 slm. In the atmosphere of H₂, the flow rate of H₂ is 20 slm. In this sequence, hydrogen is flown during the time period of 1.5 seconds, ammonia is flown during the time period of 0.5 seconds, and the time period of one cycle is 1.5 seconds. Thereafter, the AlN mask is removed by using TMAH, and then annealing is performed in the N₂ atmosphere at 850 degrees Celsius for 2 minutes. Thereafter, the AlN mask is removed by using the TMAH solution. The above processing makes it possible to activate Mg (p-type layer), and Si (n-type layer) implanted into the region implanted with the Mg. The ohmic electrodes (drain electrode and source electrode) and the gate electrode are formed on the annealed epitaxial growth substrate.

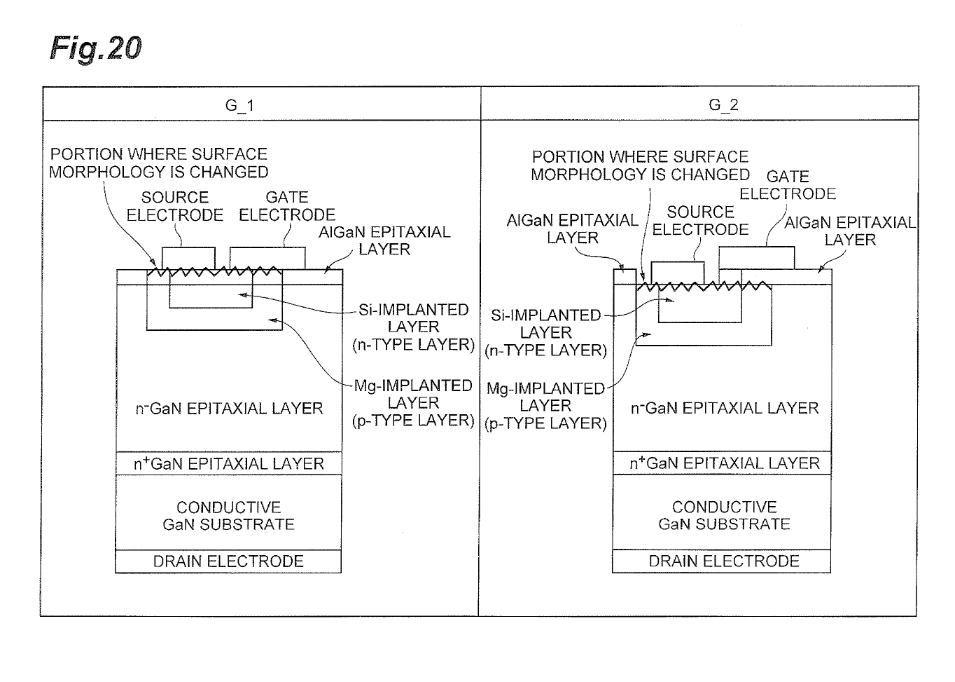

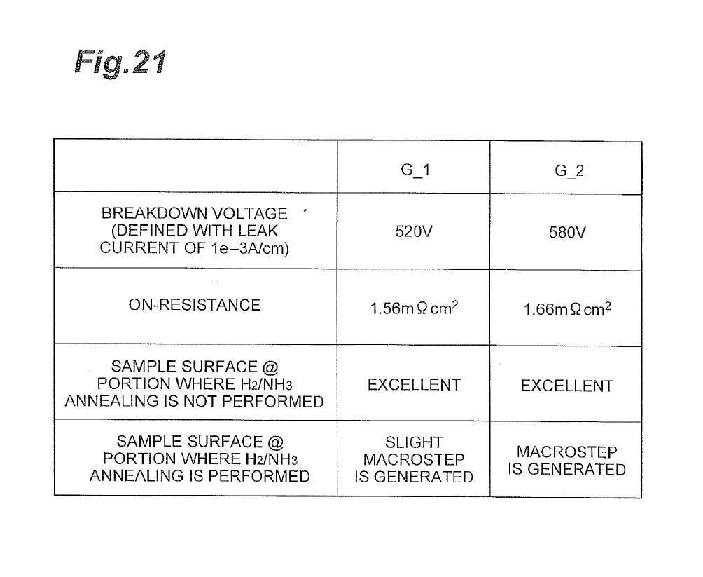

By Experiments described above, the vertical transistors having the structures shown in FIG. 20 are fabricated. With reference to FIG. 21, a description will be given of characteristics of the vertical transistors G_{—}1 and G_{—}2 fabricated by Experiments described above. With regard to the on-resistance and the breakdown voltage, the on-resistance of the vertical transistor G_{—}1 is lower than that of the vertical transistor G_{—}2. In addition, the reverse breakdown voltage of the vertical transistor G_{—}2 is higher than that of the vertical transistor G_{—}1. In each of the vertical transistors fabricated in this manner, since the H2/NH3 annealing is performed in the state where the Mg-implanted layer and the Si-implanted layer subjected to the ion implantation are exposed, the slight macro-step is generated on the epitaxial growth surface of Experiment G1. The macro-step is generated on the epitaxial growth surface of Experiment G2. In each of Experiments, the portion other than the surface of the region subjected to the ion implantation has the excellent surface morphology.

The vertical transistor fabricated in this manner includes the AlGaN channel, and can also have channels of other materials (e.g., AlInN, MOS, and MIS). In addition, the p-type well region and the n-type contact region can be applied to a vertical transistor having a MIS type or a MOS type. Further, a transistor comprising the p-type region and the n-type region are not limited to the vertical transistor, and can be applied to a lateral transistor (e.g., a high electron mobility transistor).

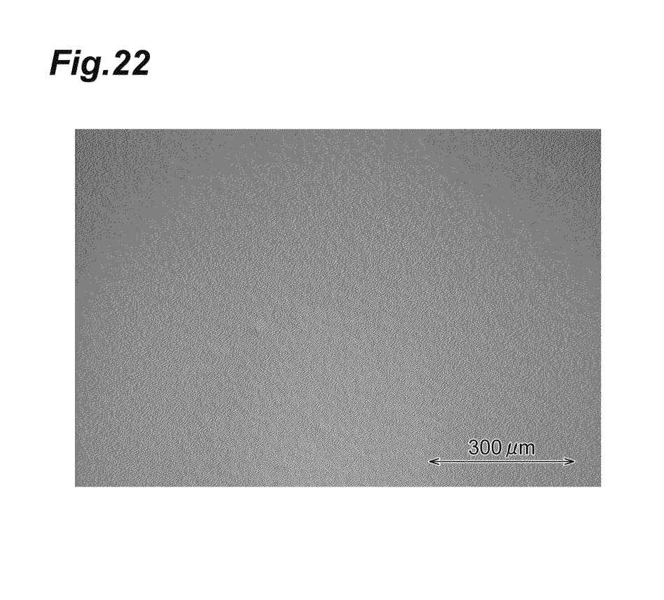

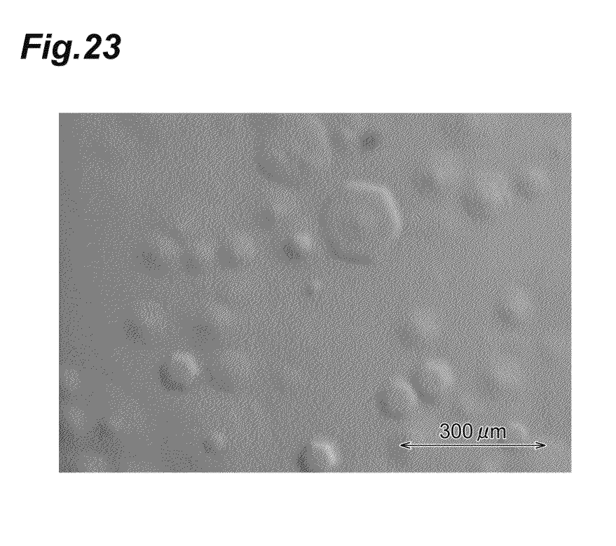

Each of FIGS. 22 and 23 is a view showing the microscope image of the appearance of the epitaxial growth surface, which has annealed with the H2/NH3. FIG. 22 is a view showing the appearance of the portion that is not exposed to the atmosphere during the H2/NH3 annealing. FIG. 23 is a view showing the appearance of the portion that is exposed to the atmosphere during the H2/NH3 annealing. Comparison of FIGS. 22 and 23 with each other shows that the morphology of the portion exposed to the H2/NH3 atmosphere is changed.

As can be seen from the semiconductor devices fabricated in Examples described above, the semiconductor devices can have the following structures.

The group III nitride semiconductor device according to the present embodiment includes the group III nitride semiconductor region. The p-type dopant is selectively implanted into a portion of the group III nitride semiconductor region, and the implanted p-type dopant is activated by the thermal treatment method according to the present embodiment.

For example, the group III nitride semiconductor device includes the Schottky barrier diode having the p-type guard ring layer, and the p-type dopant of the p-type guard ring layer is activated by the thermal treatment method according to the present embodiment.

For example, the group III nitride semiconductor device includes the vertical transistor having the p-type semiconductor region and the n-type semiconductor region, and the dopant of each of the p-type semiconductor region and the n-type semiconductor region is activated by the thermal treatment method according to the present embodiment.

For example, the group III nitride semiconductor device includes the group III nitride semiconductor region. The first portion of the group III nitride semiconductor region is selectively ion-implanted with Mg, and the second portion of the group III nitride semiconductor region is not ion-implanted. The implanted Mg is activated, and the surface of the first portion has the surface morphology different from that of that of the second portion.

For example, the group III nitride semiconductor device includes the Schottky barrier diode having the p-type guard ring semiconductor portion and the n-type semiconductor portion. The p-type dopant in the p-type guard ring layer is activated, and at least a portion of the surface of the p-type guard ring layer has the surface morphology different from that of the n-type semiconductor region.

For example, the group III nitride semiconductor device includes the vertical transistor having the p-type semiconductor layer and the n-type semiconductor layer. The dopant of the p-type semiconductor layer and the dopant of the n-type semiconductor layer are activated, and at least a portion of the surface of any of the p-type semiconductor layer and the n-type semiconductor layer has the surface morphology different from that of the other portion thereof.

The present invention is not limited to the specific structure disclosed in the present embodiment.

In the present embodiment, although examples of application to the electronic device have been shown, the present invention is useful for the activation of the p-type dopants of the p-layers of an ultraviolet LED (layers of p-AlGaN, p-AlN, and p-GaN). In addition, although the combination of the reducing gas and the nitrogen source gas in the thermal treatment has been described, there can be considered a method using a plasma process such as, e.g., a method in which plasma is used and a method in which a hydrogen plasma treatment and nitrogen plasma or ammonia plasma are alternately used. Further, although the morphology having the hexagonal hillock has been shown as an example of the morphology, the morphology encompasses the macro-step as well as the hexagonal hillock. In the photograph, although the substrate with an off angle in the vicinity of zero degrees is used, if the substrate with the off angle more than zero degrees is also used, then the surface has a morphology different from the above examples, naturally.

Thus, according to the present embodiment, there is provided the method of forming the group III nitride semiconductor capable of providing the group III nitride semiconductor exhibiting excellent conductivity. According to the present embodiment, there is provided the method of fabricating the semiconductor device capable of providing the group III nitride semiconductor exhibiting excellent conductivity. Further, according to the present embodiment, there is provided the method of performing the thermal treatment of the group III nitride semiconductor capable of providing the group III nitride semiconductor exhibiting excellent conductivity. According to the present embodiment, there is provided the group III nitride semiconductor device including the group III nitride semiconductor exhibiting excellent conductivity.

Having illustrated and described the principle of the present invention in the preferred embodiments thereof, but it should be noted that it can be understood by those skilled in the art that the present invention can be modified in arrangement and detail without departing from the principle of the invention. The present invention is by no means limited to the specific configurations disclosed in the embodiments thereof. Therefore, we claim all corrections and modifications resulting from the scope and spirit of claims.

What is claimed is:

1. A method of forming a group III nitride semiconductor, comprising the steps of:
preparing a group III nitride semiconductor, the group III nitride semiconductor containing at least one of a p-type dopant and an n-type dopant; and
performing a treatment of the group III nitride semiconductor by using a reducing gas and a nitrogen source gas to form a conductive group III nitride semiconductor,
the treatment including the steps of:
performing a first thermal treatment of the group III nitride semiconductor by using a first treatment gas including the reducing gas and the nitrogen source gas, the reducing gas and the nitrogen source gas of the first treatment being supplied to a treatment apparatus at a first flow rate and a second flow rate, respectively, and
performing a second thermal treatment of the group III nitride semiconductor by using a second treatment gas including the reducing gas and the nitrogen source gas after the first thermal treatment is performed, the reducing gas and the nitrogen source gas of the second treatment gas being supplied to the treatment apparatus at a third flow rate and a fourth flow rate, respectively,
the first flow rate being more than zero and the second flow rate being not less than zero in the first thermal treatment,
the fourth flow rate being more than zero and the third flow rate being not less than zero in the second thermal treatment, and
the second flow rate being less than the fourth flow rate.

2. The method of forming a group III nitride semiconductor according to claim 1, wherein the first thermal treatment and the second thermal treatment are alternately performed.

3. The method of forming a group III nitride semiconductor according to claim 1, wherein the first thermal treatment is performed at a temperature of not less than 800 degrees Celsius, and the second thermal treatment is performed at a temperature of not less than 800 degrees Celsius.

4. The method of forming a group III nitride semiconductor according to claim 1, wherein the first thermal treatment is performed at a temperature of not more than 1450 degrees Celsius, and the second thermal treatment is performed at a temperature of not more than 1450 degrees Celsius.

5. The method of forming a group III nitride semiconductor according to claim 1, wherein the reducing gas in the first thermal treatment contains at least any of hydrogen (H₂) and hydrochloric acid (HCl), and the reducing gas in the second thermal treatment contains at least any of hydrogen (H₂) and hydrochloric acid (HCl).

6. The method of forming a group III nitride semiconductor according to claim 1, wherein the nitrogen source gas in the first thermal treatment contains at least any of ammonia, a hydrazine-based substance, and an amine-based substance, and the nitrogen source gas in the second thermal treatment contains at least any of ammonia, the hydrazine-based substance, and the amine-based substance.

7. The method of forming a group III nitride semiconductor according to claim 1, wherein the n-type dopant includes at least any of silicon (Si), germanium (Ge), and oxygen (O).

8. The method of forming a group III nitride semiconductor according to claim 1, wherein the p-type dopant includes at least any of magnesium (Mg), calcium (Ca), carbon (C), beryllium (Be), yttrium (Y), and zinc (Zn).

9. The method of forming a group III nitride semiconductor according to claim 1, wherein the treatment further includes the steps of:
performing a third thermal treatment of the group III nitride semiconductor by using a third treatment gas, the reducing gas and the nitrogen source gas of the third treatment gas being supplied to the treatment apparatus at a fifth flow rate and a sixth flow rate, respectively, and
performing a fourth thermal treatment of the group III nitride semiconductor by using a fourth treatment gas after the third thermal treatment is performed, the reducing gas and the nitrogen source gas of the fourth treatment gas being supplied to the treatment apparatus at a seventh flow rate and an eighth flow rate, respectively.

10. The method of forming a group III nitride semiconductor according to claim 1, wherein the nitrogen source gas is not supplied in the first thermal treatment.

11. The method of forming a group III nitride semiconductor according to claim 1, wherein the reducing gas is not supplied in the second thermal treatment.

12. The method of forming a group III nitride semiconductor according to claim 1, wherein the group III nitride semiconductor to which the first thermal treatment and the second thermal treatment have been applied includes a p-type conductivity region.

13. The method of forming a group III nitride semiconductor according to claim 1, wherein the group III nitride semiconductor to which the first thermal treatment and the second thermal treatment have been applied, includes an n-type conductivity region.

14. The method of forming a group III nitride semiconductor according to claim 1, wherein the group III nitride semiconductor to which the first thermal treatment and the second thermal treatment have been applied comprises both of the p-type dopant and the n-type dopant.

15. The method of forming a group III nitride semiconductor according to claim 1, wherein the group III nitride semiconductor to which the first thermal treatment and the second thermal treatment have been applied includes a first portion and a second portion, the first portion of the group III nitride semiconductor exhibits an n-type conductivity, and the second portion of the group III nitride semiconductor exhibits a p-type conductivity.

16. The method of forming a group III nitride semiconductor according to claim 1, further comprising the step of growing a group III nitride semiconductor layer in a growth reactor, wherein preparing the group III nitride semiconductor includes the step of ion-implanting the dopant into the group III nitride semiconductor layer to form the group III nitride semiconductor.

17. The method of forming a group III nitride semiconductor according to claim 16, further comprising the step of forming a mask having a pattern on the group III nitride semiconductor layer, wherein preparing the group III nitride semiconductor includes the step of ion-implanting the dopant into the group III nitride semiconductor layer by using the mask to form the group III nitride semiconductor.

18. The method of forming a group III nitride semiconductor according to claim 1, wherein the step of preparing the group III nitride semiconductor includes the step of supplying the dopant and a material gas to a growth reactor to grow a group III nitride semiconductor layer.

19. The method of forming a group III nitride semiconductor according to claim 18, wherein the material gas contains an organometallic material, and the dopant includes the p-type dopant.

20. The method of forming a group III nitride semiconductor according to claim 1, wherein
the conductive group III nitride semiconductor includes a first region and a second region, and the first region and the second region are arranged in turn from a surface of the group III nitride semiconductor in a depth direction,
the conductive group III nitride semiconductor has a p-type dopant profile and an n-type dopant profile, and the p-type dopant profile and the n-type dopant profile are defined from the surface of the group III nitride semiconductor in the depth direction,
an n-type dopant concentration in the n-type dopant profile is higher than a p-type dopant concentration in the p-type dopant profile in the first region of the conductive group III nitride semiconductor, and
the p-type dopant concentration in the p-type dopant profile is higher than the n-type dopant concentration in the n-type dopant profile in the second region of the conductive group III nitride semiconductor.

21. The method of forming a group III nitride semiconductor according to claim 1, wherein the group III nitride semiconductor includes at least any of GaN, InN, AlN, AlGaN, InGaN, InAlN, and InAlGaN.

22. A method of fabricating a semiconductor device using a group III nitride semiconductor, comprising the steps of:
preparing a group III nitride semiconductor, the group III nitride semiconductor containing at least one of a p-type dopant and an n-type dopant; and
performing a treatment of the group III nitride semiconductor by using a reducing gas and a nitrogen source gas to form a conductive group III nitride semiconductor,
the treatment including the steps of:
performing a first thermal treatment of the group III nitride semiconductor by using a first treatment gas, the reducing gas and the nitrogen source gas of the first treatment gas are supplied to a treatment apparatus at a first flow rate and a second flow rate, and
performing a second thermal treatment of the group III nitride semiconductor by using second treatment gas after the first thermal treatment is performed, the reducing gas and the nitrogen source gas of the second treatment gas are supplied to the treatment apparatus at a third flow rate and a fourth flow rate, respectively,
the first flow rate being more than zero and the second flow rate being not less than zero in the first thermal treatment,
the fourth flow rate being more than zero and the third flow rate being not less than zero in the second thermal treatment, and
the second flow rate being less than the fourth flow rate.

23. The method of fabricating a semiconductor device according to claim 22, wherein the first thermal treatment and the second thermal treatment are alternately performed.

24. The method of fabricating a semiconductor device according to claim 22, wherein the first thermal treatment is performed at a temperature of not less than 800 degrees Celsius, and the second thermal treatment is performed at a temperature of not less than 800 degrees Celsius.

25. The method of fabricating a semiconductor device according to claim 22, wherein the first thermal treatment is performed at a temperature of not more than 1450 degrees Celsius, and the second thermal treatment is performed at a temperature of not more than 1450 degrees Celsius.

26. The method of fabricating a semiconductor device according to claim 22, wherein the reducing gas in the first thermal treatment contains at least any of hydrogen (H₂) and hydrochloric acid (HCl), and the reducing gas in the second thermal treatment contains at least any of hydrogen (H₂) and hydrochloric acid (HCl).

27. The method of fabricating a semiconductor device according to claim 22, wherein the nitrogen source gas of the first thermal treatment contains at least any of ammonia, a hydrazine-based substance, and an amine-based substance, and the nitrogen source gas of the second thermal treatment contains at least any of ammonia, the hydrazine-based substance, and the amine-based substance.

28. The method of fabricating a semiconductor device according to claim 22, wherein the n-type dopant includes at least any of silicon (Si), germanium (Ge), and oxygen (O).

29. The method of fabricating a semiconductor device according to claim 22, wherein the p-type dopant includes at least any of magnesium (Mg), calcium (Ca), carbon (C), beryllium (Be), yttrium (Y), and zinc (Zn).

30. The method of fabricating a semiconductor device according to claim 22, further comprising the step of growing a group III nitride semiconductor layer in a growth reactor,
preparing the group III nitride semiconductor includes the step of performing one or more ion-implantations of the dopant into the group III nitride semiconductor layer to form the group III nitride semiconductor, and
acceleration energies of the ion implantations are different from each other.

31. The method of fabricating a semiconductor device according to claim 30, further comprising the step of forming a mask having a pattern on the group III nitride semiconductor layer,
wherein preparing the group III nitride semiconductor includes the step of ion-implanting the dopant into the group III nitride semiconductor layer by using the mask to form the group III nitride semiconductor layer.

32. The method of fabricating a semiconductor device according to claim 31, further comprising the steps of:
growing a mask film of a material different from that of the group III nitride semiconductor layer before the mask is formed; and
forming a resist mask having a pattern on the mask film,
in the step of forming the mask, the mask film being etched by using the resist mask to form the mask.

33. The method of fabricating a semiconductor device according to claim 31, wherein a surface of the group III nitride semiconductor layer comprises at least one of GaN and AlGaN, and the mask comprises a group III nitride different from a material of the surface of the group III nitride semiconductor layer.

34. The method of fabricating a semiconductor device according to claim 31, wherein the mask includes at least one of an AlN layer and an AlGaN layer.

35. The method of fabricating a semiconductor device according to claim 31, further comprising the step of, after the treatment of the group III nitride semiconductor is performed, removing the mask to expose a surface of the group III nitride semiconductor layer.

36. The method of fabricating a semiconductor device according to claim 35, wherein the removal of the mask is performed by using an alkaline aqueous solution.

37. The method of fabricating a semiconductor device according to claim 22, wherein a surface of the conductive group III nitride semiconductor to which the first thermal treatment and the second thermal treatment have been applied includes a p-type conductivity region and an n-type conductivity region.

38. The method of fabricating a semiconductor device according to claim 22, wherein the semiconductor device includes a Schottky diode, and the conductive group III nitride semiconductor includes a p-type guard ring of the Schottky diode.

39. The method of fabricating a semiconductor device according to claim 22, further comprising the step of forming a Schottky electrode such that the Schottky electrode is in contact with the conductive group III nitride semiconductor.

40. The method of fabricating a semiconductor device according to claim 22, wherein the semiconductor device includes a transistor, and the conductive group III nitride semiconductor includes a p-type well of the transistor.

41. The method of fabricating a semiconductor device according to claim 22, wherein
the semiconductor device includes a transistor,
the conductive group III nitride semiconductor includes a first region and a second region, and the first region and the second region are arranged in turn from a surface of the group III nitride semiconductor in a depth direction,
the conductive group III nitride semiconductor has a first conductivity type dopant profile and a second conductivity type dopant profile, and the first conductivity type dopant profile and the second conductivity type dopant profile are defined from the surface of the group III nitride semiconductor in the depth direction,
a first conductivity type dopant concentration in the first conductivity type dopant profile is higher than a second conductivity type dopant concentration in the second conductivity type dopant profile in the first region of the conductive group III nitride semiconductor, and
the second conductivity type dopant concentration in the second conductivity type dopant profile is higher than the first conductivity type dopant concentration in the first conductivity type dopant profile in the second region of the conductive group III nitride semiconductor.

42. The method of fabricating a semiconductor device according to claim 41, wherein
the first conductivity type dopant profile indicates an n-type dopant profile,
the second conductivity type dopant profile indicates a p-type dopant profile,
the conductive group III nitride semiconductor includes a third region, and the third region extends from the second region to the surface of the group III nitride semiconductor so as to surround the first region,
the first region includes a source region of the transistor, and
the second region and the third region include a well region of the transistor.

43. The method of fabricating a semiconductor device according to claim 42, further comprising the step of forming an electrode such that the electrode is in contact with the well region and the source region.

44. The method of fabricating a semiconductor device according to claim 42, further comprising the steps of:
forming a gate film on the well region; and
forming a gate electrode on the gate film.

45. The method of fabricating a semiconductor device according to claim 22, wherein
the semiconductor device includes a junction diode,
the conductive group III nitride semiconductor includes a first region and a second region, and the first region and the second region are arranged in turn from a surface of the group III nitride semiconductor in a depth direction,
the group III nitride semiconductor has a p-type dopant profile and an n-type dopant profile, and the p-type dopant profile and the n-type dopant profile are defined from the surface of the group III nitride semiconductor in the depth direction,
a p-type dopant concentration in the p-type dopant profile is higher than an n-type dopant concentration in the n-type dopant profile in the first region of the group III nitride semiconductor, and
the n-type dopant concentration in the n-type dopant profile is higher than the p-type dopant concentration in the p-type dopant profile in the second region of the group III nitride semiconductor,
the method of fabricating a semiconductor device according to claim 22, further comprising the step of forming an electrode in contact with the first region of the conductive group III nitride semiconductor.

46. The method of fabricating a semiconductor device according to claim 45, wherein the first region and the second region of the conductive group III nitride semiconductor constitute a pn junction for the junction diode.

47. The method of fabricating a semiconductor device according to claim 45, wherein the conductive group III nitride semiconductor includes an i-type region provided between the first region and the second region, and the first region, the i-type region, and the second region constitute a pin junction structure for the junction diode.

48. The method of fabricating a semiconductor device according to claim 22, further comprising the steps of:
preparing a conductive substrate having a primary surface and a back surface; and
forming a back side electrode on the back surface of the conductive substrate after the conductive group III nitride semiconductor is formed, wherein
preparing the group III nitride semiconductor includes the step of forming the group III nitride semiconductor on the primary surface of the conductive substrate such that at least one of the p-type dopant and the n-type dopant is contained.

49. The method of fabricating a semiconductor device according to claim 22, wherein the nitrogen source gas is not supplied in the first thermal treatment, and the fourth flow rate is more than zero in the second thermal treatment.

50. The method of fabricating a semiconductor device according to claim 22, further comprising the steps of:
performing observation of a surface of the group III nitride semiconductor after the treatment is performed using the reducing gas and the nitrogen source gas; and
determining to perform a subsequent treatment in the method of fabricating a semiconductor device when the observation shows that a morphology is in the surface of the group III nitride semiconductor.

51. The method of fabricating a semiconductor device according to claim 50, further comprising the step of, after the determination, forming an electrode on the conductive group III nitride semiconductor.

52. The method of fabricating a semiconductor device according to claim 22, wherein preparing the group III nitride semiconductor includes the step of any of regrowth and burying growth of the group III nitride semiconductor.

53. A method of performing a thermal treatment of a group III nitride semiconductor, comprising the steps of:
preparing an ion-implanted group III nitride semiconductor; and
performing the thermal treatment of the ion-implanted group III nitride semiconductor at a temperature in a range of not less than 800 degrees Celsius and not more than 1450 degrees Celsius by using a nitrogen source gas capable of providing a nitrogen source for a constituent element of the group III nitride semiconductor and a reducing gas capable of providing a reducing atmosphere,
wherein the thermal treatment includes the steps of:
performing a first treatment in which a flow rate of the reducing gas is more than zero, and
performing a second treatment in which a flow rate of the nitrogen source gas is more than zero, the flow rate for the nitrogen gas in the first treatment being less than the flow rate for the nitrogen source gas in the second treatment.

54. The method of performing a thermal treatment according to claim 53, wherein the first treatment and the second treatment are performed alternately.

55. A method of performing a thermal treatment of a group III nitride semiconductor, comprising the steps of:
preparing an ion-implanted group III nitride semiconductor; and
performing the thermal treatment of the ion-implanted group III nitride semiconductor at a temperature in a range of not less than 800 degrees Celsius and not more than 1450 degrees Celsius by using a nitrogen source gas and a reducing gas, the nitrogen source gas serving as a nitrogen source for the group III nitride semiconductor, and the reducing gas providing a reducing atmosphere capable of reducing the group III nitride semiconductor, wherein
the thermal treatment comprises adjusting a flow rate of the reducing gas and a flow rate of the nitrogen source gas to perform a first treatment such that the ion-implanted group III nitride semiconductor is exposed to the reducing atmosphere containing the reducing gas, and, after the first treatment, performing a second treatment such that the ion-implanted group III nitride semiconductor is exposed to a nitrogen source atmosphere containing the nitrogen source gas.

56. The method of performing a thermal treatment according to claim 55, wherein the first treatment and the second treatment are performed alternately.

57. A method of performing a thermal treatment of a group III nitride semiconductor, comprising the steps of:
preparing a group III nitride semiconductor containing at least one of a p-type dopant and an n-type dopant; and
performing a treatment of the group III nitride semiconductor by using a reducing gas and a nitrogen source gas,
the treatment including the steps of:
performing a first thermal treatment of the group III nitride semiconductor by using a first treatment gas, the reducing gas and the nitrogen source gas of the first treatment gas being supplied to a treatment apparatus at a first flow rate and a second flow rate, respectively, and
performing a second thermal treatment of the group III nitride semiconductor after the first thermal treatment is performed, the reducing gas and the nitrogen source gas of the second treatment gas being supplied to the treatment apparatus to at a third flow rate and a fourth flow rate,
the first flow rate being more than zero and the second flow rate being not less than zero in the first thermal treatment,
the fourth flow rate being more than zero and the third flow rate being not less than zero in the second thermal treatment, and
the second flow rate being less than the fourth flow rate.

58. The method of performing a thermal treatment according to claim 57, wherein the first thermal treatment and the second thermal treatment are performed alternately.

59. A group III nitride semiconductor device comprising a group III nitride semiconductor region, a p-type dopant being selectively implanted into a portion of the group III nitride semiconductor region, and the implanted p-type dopant being activated by the method according to claim 57.

60. A group III nitride semiconductor device, the group III nitride semiconductor device including a Schottky barrier diode, the Schottky barrier diode having a p-type guard ring, and a p-type dopant of the p-type guard ring is activated by the method according to claim 57.

61. A group III nitride semiconductor device, the group III nitride semiconductor device including a vertical transistor, the vertical transistor having a p-type semiconductor for a well and an n-type semiconductor for an n-type contact, and a dopant of each of the p-type semiconductor and the n-type semiconductor being activated by the method of claim 57.

62. A group III nitride semiconductor device comprising a group III nitride semiconductor region, the group III nitride semiconductor region having a first portion and a second portion, the first portion of the group III nitride semiconductor region being selectively ion-implanted with Mg, the second portion of the group III nitride semiconductor region being not ion-implanted, the implanted Mg being activated, and a surface of the first portion having a surface morphology different from that of a surface of the second portion.

63. A group III nitride semiconductor device, the group III nitride semiconductor device including a Schottky barrier diode, the Schottky barrier diode having a p-type guard ring and an n-type semiconductor region, a p-type dopant of the p-type guard ring being activated, and at least a portion of a surface of the p-type guard ring having a surface morphology different from that of the n-type semiconductor region.

64. A group III nitride semiconductor device, the group III nitride semiconductor device including a vertical transistor, the vertical transistor having a p-type semiconductor region for a well and an n-type semiconductor region for an n-type contact, a dopant of each of the p-type semiconductor region and the n-type semiconductor region being activated, and at least a portion of a surface of any of the p-type semiconductor region and the n-type semiconductor region having surface morphology different from that of the other portion thereof.
